(19) United States
(12) Patent Application Publication
(10) Pub. No.: US 2025/0081428 A1
(43) Pub. Date: Mar. 6, 2025

(54) MEMORY AND METHOD OF FABRICATING THEREOF, MEMORY SYSTEM AND ELECTRONIC DEVICE

(71) Applicant: YANGTZE MEMORY TECHNOLOGIES CO., LTD., Wuhan (CN)

(72) Inventor: Hao ZHANG, Wuhan (CN)

(21) Appl. No.: 18/542,167

(22) Filed: Dec. 15, 2023

Related U.S. Application Data
(63) Continuation of application No. PCT/CN2023/117353, filed on Sep. 6, 2023.

(51) Int. Cl. H10B 12/00

(52) U.S. Cl. CPC H10B 12/315; H10B 12/0335

(57) ABSTRACT

The present disclosure provides a memory that includes a first semiconductor structure including a vertical transistor. A first and second insulating structures are stacked in turn on the first semiconductor structure. A contact structure penetrates through the first insulating structure and connects with a semiconductor body of the vertical transistor. A first electrode structure includes a first electrode layer penetrating through at least part of the first insulating structure and a second electrode layer penetrating through the second insulating structure. The first electrode layer may cover a sidewall of at least part of the contact structure and connected with the contact structure, and the second electrode layer is connected with the first electrode layer. A second electrode structure may include a first and second part in the first and second insulating structures, respectively. A capacitor dielectric layer may be between the first electrode structure and the second electrode structure.

### CROSS-REFERENCE TO RELATED APPLICATIONS

This application is a continuation of International Application No. PCT/CN2023/117353, filed on Sep. 6, 2023, which is incorporated herein by reference in its entirety.

### TECHNICAL FIELD

Implementations of the present disclosure relate to the field of semiconductor, in particular to a memory and a method of fabricating thereof, a memory system and an electronic device.

### BACKGROUND

Dynamic random access memory (DRAM) is a memory device commonly used in electronic system and consists of many repeating memory cells each including a capacitor and a transistor.

With the development of semiconductor technology, DRAM is developing towards high density and high-integration level, and the feature size of capacitor is decreasing such that the capacitance value of the capacitor is decreasing.

### SUMMARY

According to one aspect of the present disclosure, a memory is provided. The memory may include a first semiconductor structure that includes a vertical transistor. The memory may include a first insulating structure and a second insulating structure stacked in turn on the first semiconductor structure. The memory may include a contact structure penetrating through the first insulating structure and connected with a semiconductor body of the vertical transistor. The memory may include a first electrode structure. The first electrode structure may include a first electrode layer penetrating through at least part of the first insulating structure and a second electrode layer penetrating through the second insulating structure. The first electrode layer may cover a sidewall of at least part of the contact structure and being connected with the contact structure. The second electrode layer may be connected with the first electrode layer. The memory may include a second electrode structure covering a first part in the first insulating structure and a second part in the second insulating structure. The first part may cover a sidewall of part of the first electrode layer. The second part may cover a sidewall of part of the second electrode layer. The memory may include a capacitor dielectric layer between the first electrode structure and the second electrode structure.

In some implementations, the first insulating structure may include a first insulating layer and a first support layer stacked in turn on the first semiconductor structure. In some implementations, the first insulating layer may be disposed as being spaced apart from the first support layer. In some implementations, the first part may be located between the first insulating layer and the first support layer.

In some implementations, the contact structure may include a metal layer and a semiconductor layer. In some implementations, the metal layer may penetrate through the first support layer and may extend into the first insulating layer. In some implementations, the semiconductor layer may be located between the semiconductor layer and the metal layer. In some implementations, the first electrode layer may include a first sub-electrode layer over the semiconductor layer and covering sidewall of the metal layer.

In some implementations, the first electrode layer further includes a second sub-electrode layer between the semiconductor layer and the metal layer.

In some implementations, the contact structure may include a metal layer and a semiconductor layer. In some implementations, the metal layer may penetrate through the first support layer and may extend to between the first insulating layer and the first support layer. In some implementations, the semiconductor layer may be located between the semiconductor layer and the metal layer. In some implementations, the first electrode layer may be located over the first semiconductor structure and may cover a sidewalls of the semiconductor layer and the metal layer.

In some implementations, the contact structure may include a connection layer between the semiconductor layer and the metal layer.

In some implementations, the second insulating structure may include a second support layer. In some implementations, the second support layer may be disposed as being spaced apart from the first insulating structure. In some implementations, the second part may be located between the first insulating structure and the second support layer.

In some implementations, the second insulating structure further includes a third support layer. In some implementations, the third support layer may be disposed as being spaced apart from the second support layer. In some implementations, the second part may be further located between the second support layer and the third support layer.

According to another aspect of the present disclosure, a method of fabricating a memory is provided. The method may include providing a first semiconductor structure. The first semiconductor structure may include a vertical transistor. The method may include forming a first insulating structure covering the first semiconductor structure. The method may include forming a contact structure penetrating through the first insulating structure. The contact structure may be connected with a semiconductor body of the vertical transistor. The method may include forming a second insulating structure covering the contact structure and the first insulating structure. The method may include forming a first electrode structure. The first electrode structure may include a first electrode layer penetrating through at least part of the first insulating structure and a second electrode layer penetrating through the second insulating structure. The first electrode layer may cover a sidewall of at least part of the contact structure and is connected with the contact structure. The second electrode layer may be connected with the first electrode layer. The method may include forming a second electrode structure. The second electrode structure may include a first part in the first insulating structure and a second part in the second insulating structure. The first part may cover a sidewall of part of the first electrode layer. The second part may cover a sidewall of part of the second electrode layer. The method may include forming a capacitor dielectric layer. The capacitor dielectric layer may be located between the first electrode structure and the second electrode structure.

In some implementations, the method may include forming a first insulating structure material layer covering the first semiconductor structure. In some implementations, the first insulating structure material layer may include a first insulating material layer, a first sacrificial-material layer, and a first support material layer stacked in turn. In some implementations, the method may include forming a first through hole penetrating through the first insulating structure material layer. In some implementations, a bottom of the first through hole may include the semiconductor body. In some implementations, the forming the contact structure penetrating through the first insulating structure may include forming a semiconductor layer in the first through hole and connected with the semiconductor body. In some implementations, a size of the semiconductor layer may be smaller than a size of the first insulating material layer in a thickness direction of the first semiconductor structure. In some implementations, the forming of the contact structure penetrating through the first insulating structure may include forming a metal layer on the semiconductor layer and connected with the semiconductor layer. In some implementations, the contact structure may include the semiconductor layer and the metal layer. In some implementations, the forming the first electrode structure may include, after forming the semiconductor layer, forming a first sub-through hole based on a topography of the first through hole. In some implementations, a bottom of the first sub-through hole may expose the semiconductor layer. In some implementations, the forming of the contact structure penetrating through the first insulating structure may include forming the first electrode layer covering sidewall and bottom of the first sub-through hole. In some implementations, the forming of the metal layer on the semiconductor layer may include forming the metal layer in the first sub-through hole formed with the first electrode layer.

In some implementations, the method may further include forming a first insulating structure material layer covering the first semiconductor structure. In some implementations, the first insulating structure material layer may include a first insulating material layer, a first sacrificial-material layer, and a first support material layer stacked in turn. In some implementations, the method may include forming a first through hole penetrating through the first insulating structure material layer. In some implementations, a bottom of the first through hole may expose the semiconductor body. In some implementations, the forming the first electrode structure may include forming the first electrode layer covering sidewall of the first through hole. In some implementations, the forming the first electrode structure may include forming a first sub-through hole based on a topography of the first through hole, a bottom of the first sub-through hole exposing the semiconductor body. In some implementations, the forming of the contact structure penetrating through the first insulating structure may include forming a semiconductor layer in the first sub-through hole and connected with the semiconductor body. In some implementations, a size of the semiconductor layer may be greater than a size of the first insulating material layer and smaller than a sum of sizes of the first insulating material layer and the first sacrificial-material layer in a thickness direction of the first semiconductor structure. In some implementations, the forming of the contact structure penetrating through the first insulating structure may include forming a metal layer on the semiconductor layer and connected with the semiconductor layer. In some implementations, the contact structure may be the semiconductor layer and the metal layer.

In some implementations, the method may include forming a second insulating structure material layer covering the first insulating structure material layer, the first electrode layer, and the contact structure. In some implementations, the second insulating structure material layer may include a second sacrificial-material layer and a second support material layer stacked in turn. In some implementations, the method may include forming a second through hole penetrating through the second insulating structure material layer. In some implementations, a bottom of the second through hole may expose the first electrode layer and the contact structure. In some implementations, the forming the first electrode structure may further include forming the second electrode layer at least covering sidewall of the second through hole. In some implementations, the forming the first electrode structure may further include forming a second sub-through hole based on a topography of the second through hole. In some implementations, the method may further include filling the second sub-through hole to form an electrode contact layer.

In some implementations, the memory may include a plurality of the first electrode structures. In some implementations the method may further include forming a third through hole penetrating through the second insulating structure material layer, the first support material layer, and the first sacrificial-material layer. In some implementations, the third through hole may be located between adjacent two of the first electrode structures. In some implementations, a sidewall of the third through hole may expose part of the first electrode layer and part of the second electrode layer. In some implementations, a bottom of the third through hole may expose the first insulating material layer. In some implementations, the forming of the capacitor dielectric layer may include forming a first sub-capacitor dielectric layer covering the exposed part of the first electrode layer. In some implementations, the forming of the capacitor dielectric layer may include forming a second sub-capacitor dielectric layer covering the exposed part of the second electrode layer. In some implementations, the capacitor dielectric layer may include the first sub-capacitor dielectric layer and the second sub-capacitor dielectric layer. In some implementations, the forming of the second electrode structure may include forming the first part covering the first sub-capacitor dielectric layer. In some implementations, the forming the second electrode structure may include forming the second part covering the second sub-capacitor dielectric layer.

In some implementations, the forming the third through hole penetrating through the second insulating structure material layer, the first support material layer, and the first sacrificial-material layer may include etching down the second support material layer according to a mask pattern to form a first opening. In some implementations, a bottom of the first opening may expose the second sacrificial-material layer. In some implementations, a remaining portion of the second support material layer may constitute a second support layer. In some implementations, the forming the third through hole penetrating through the second insulating structure material layer, the first support material layer, and the first sacrificial-material layer may include removing the second sacrificial-material layer according to the first opening to form a first gap. In some implementations, a sidewall of the first gap may expose part of the second electrode layer. In some implementations, a bottom of the first gap may expose the first support material layer. In some implementations, the second insulating structure may include the second support layer. In some implementations, the forming the third through hole penetrating through the second insulating structure material layer, the first support material layer, and the first sacrificial-material layer may include etching down the first support material layer according to the mask pattern to form a second opening. In some implementations, a bottom of the second opening may expose the first sacrificial-material layer. In some implementations, a remaining portion of the first support material layer may constitute a first support layer. In some implementations, the forming the third through hole penetrating through the second insulating structure material layer, the first support material layer, and the first sacrificial-material layer may include removing the first sacrificial-material layer according to the second opening to form a second gap. In some implementations, a sidewall of the second gap may include part of the first electrode layer. In some implementations, a bottom of the second gap may expose the first insulating material layer. In some implementations, a remaining portion of the first insulating material layer may constitute a first insulating layer. In some implementations the first insulating structure may include the first insulating layer and the first support layer.

In some implementations, the forming the first sub-capacitor dielectric layer covering the exposed part of the first electrode layer may include forming the first sub-capacitor dielectric layer in the second gap. In some implementations, the forming the first part covering the first sub-capacitor dielectric layer may include forming the first part in the second gap formed with the first sub-capacitor dielectric layer. In some implementations, the forming of the second sub-capacitor dielectric layer covering the exposed part of the second electrode layer may include forming the second sub-capacitor dielectric layer in the first gap. In some implementations, the forming the second part covering the second sub-capacitor dielectric layer may include forming the second part in the first gap formed with the second sub-capacitor dielectric layer.

In some implementations, the second insulating structure material layer may further include a third sacrificial-material layer and a third support material layer stacked in turn. In some implementations, the third sacrificial-material layer may be located between the second support material layer and the third support material layer. In some implementations, the forming the third through hole penetrating through the second insulating structure material layer, the first support material layer, and the first sacrificial-material layer may include etching down the third support material layer according to the mask pattern to form a third opening. In some implementations, a bottom of the third opening may expose the third sacrificial-material layer. In some implementations, a remaining portion of the third support material layer may constitute a third support layer. In some implementations, the forming the third through hole penetrating through the second insulating structure material layer, the first support material layer, and the first sacrificial-material layer may include removing the third sacrificial-material layer according to the third opening to form a third gap. In some implementations, a sidewall of the third gap exposing part of the second electrode layer. In some implementations, a bottom of the third gap may expose the second support material layer. In some implementations, the second insulating structure may further include the third support layer.

In some implementations, the forming of the second sub-capacitor dielectric layer covering the exposed part of the second electrode layer further may include forming the second sub-capacitor dielectric layer in the third gap. In some implementations, the forming the second part covering the second sub-capacitor dielectric layer may include forming the second part in the third gap formed with the second sub-capacitor dielectric layer.

In some implementations, an etch-selectivity ratio of the second sacrificial-material layer may be greater than that of the third sacrificial-material layer.

According to another aspect of the present disclosure, a memory system is provided. The memory system may include a memory. The memory may include a first semiconductor structure. The first semiconductor structure may include a vertical transistor. The memory may include a first insulating structure and a second insulating structure stacked in turn on the first semiconductor structure. The memory may include a contact structure penetrating through the first insulating structure and connected with a semiconductor body of the vertical transistor. The memory may include a first electrode structure may include a first electrode layer penetrating through at least part of the first insulating structure and a second electrode layer penetrating through the second insulating structure. The first electrode layer may cover a sidewall of at least part of the contact structure and may be connected with the contact structure, and the second electrode layer being connected with the first electrode layer. The memory may include a second electrode structure. The second electrode structure may include a first part in the first insulating structure and a second part in the second insulating structure. The first part may cover a sidewall of part of the first electrode layer. The second part may cover a sidewall of part of the second electrode layer. The memory may include a capacitor dielectric layer between the first electrode structure and the second electrode structure. The memory system may include a memory controller coupled to the memory and configured to control the memory.

According to a further aspect of the present disclosure, an electronic device is provided. The electronic device may include a memory system. The memory system may include a memory. The memory may include a first semiconductor structure comprising a vertical transistor. The memory may include a first insulating structure and a second insulating structure stacked in turn on the first semiconductor structure. The memory may include a contact structure penetrating through the first insulating structure and connected with a semiconductor body of the vertical transistor. The memory may include a first electrode structure. The first electrode structure may include a first electrode layer penetrating through at least part of the first insulating structure and a second electrode layer penetrating through the second insulating structure. The first electrode layer may cover a sidewall of at least part of the contact structure and being connected with the contact structure. The second electrode layer may be connected with the first electrode layer. The memory may include a second electrode structure. The second electrode structure may include a first part in the first insulating structure and a second part in the second insulating structure. The first part may cover a sidewall of part of the first electrode layer. The second part may cover a sidewall of part of the second electrode layer. The memory may include a capacitor dielectric layer between the first electrode structure and the second electrode structure. The memory system may include a memory controller coupled to the memory and configured to control the memory. The electronic device may include a host coupled to the memory system.

In implementations of the present disclosure, it may be possible to increase the feature size of a first electrode structure by providing a first electrode layer penetrating through at least part of a first insulating structure and a second electrode layer penetrating through a second insulating structure. Moreover, it may be possible to increase feature size of a second electrode structure by providing a first part covering sidewall of part of the first electrode layer and a second part covering sidewall of part of the second electrode layer. In this way, the effective direct-facing area between the first electrode structure and the second electrode structure may be increased, thereby increasing the capacitance value of a capacitor.

### BRIEF DESCRIPTION OF DRAWINGS

FIG. 1a is a sectional diagram of a memory, according to an example implementation of the present disclosure.

FIG. 1b is a top view diagram of a memory, according to an example implementation.

FIG. 2a is a sectional diagram I of a memory, according to an example implementation of the present disclosure.

FIG. 2b is a sectional diagram II of a memory, according to an example implementation of the present disclosure.

FIG. 3a is a sectional diagram III of a memory, according to an example implementation of the present disclosure.

FIG. 3b is a sectional diagram IV of a memory, according to an example implementation of the present disclosure.

FIG. 4 is a flow chart of a method of fabricating a memory, according to an example implementation of the present disclosure.

FIGS. 5a to 5t are diagram I of a fabrication process of a memory, according to an example implementation of the present disclosure.

FIGS. 6a to 6e are diagram II of a fabrication process of a memory, according to an example implementation of the present disclosure.

FIGS. 7a to 7j are diagram III of a fabrication process of a memory, according to an example implementation of the present disclosure.

FIGS. 8a to 8c are diagram IV of a process of fabricating a memory, according to an implementation of the present disclosure.

### DETAILED DESCRIPTION

The technical solution of the present disclosure will be further described in detail below in connection with the accompanying drawings and implementations. Although example implementations of the present disclosure are shown in drawings, it is to be appreciated that the present disclosure may be implemented in various forms rather than being limited to the implementations as set forth herein. In contrast, these implementations are provided to understand the present disclosure more thoroughly and convey the scope of the present disclosure completely to those skilled in the art.

The present disclosure will be described in more detail in the following paragraphs with reference to figures illustratively. The advantages and features of the present disclosure will become more clear according to the following description and claims. It is noted that the drawings are all in very simplified form and in non-precise scale, they are only for the purpose of illustrating implementations of the present disclosure in a convenient and clear way.

Terms “first”, “second”, etc. in implementations of the present disclosure are used to distinguish similar objects and not necessarily to describe particular order or sequential order.

It is to be noted that technical solutions recorded in implementations of the present disclosure may be combined arbitrarily if there is no conflict.

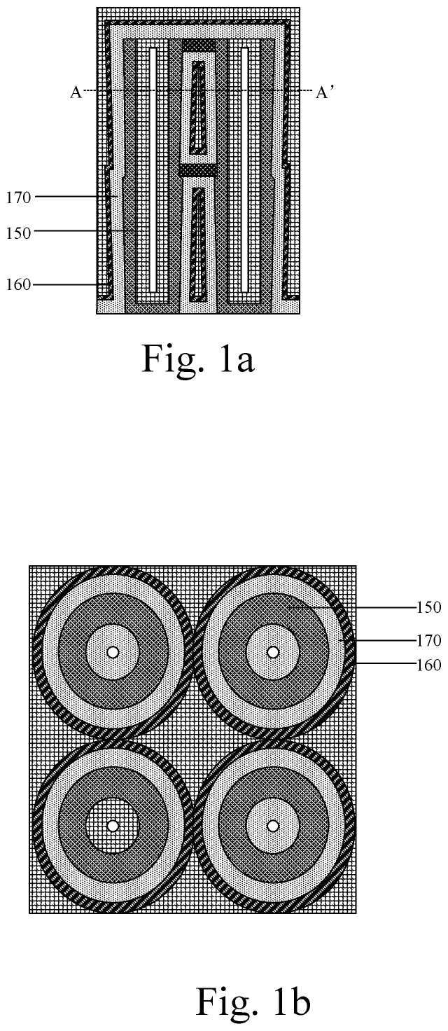

FIG. 1a is a sectional diagram of a memory, according to an example implementation. FIG. 1b is a top view diagram of the memory taken along sectional line AA′ in FIG. 1a. Referring to FIGS. 1a and 1b, the memory includes a capacitor including a bottom electrode 150, a top electrode 160, and a capacitor dielectric layer 170 between the top electrode 160 and the bottom electrode 150.

With the increasing integration level of DRAM and the decreasing feature size of the capacitor, the effective direct-facing area between the top electrode 160 and the bottom electrode 150 is decreasing. The capacitance value of the capacitor is related to the size of the capacitor, and the effective direct-facing area between the top electrode 160 and the bottom electrode 150. In an example, as the feature size of the capacitor and the effective direct-facing area between the top electrode 160 and the bottom electrode 150 decreases, the capacitance value of the capacitor decreases.

It is to be noted that the overlapping area between the top electrode 160 and the bottom electrode 150 is the effective direct-facing area between the top electrode 160 and the bottom electrode 150.

In view of this, implementations of the present disclosure provide a memory and a method of fabricating thereof, a memory system and an electronic device.

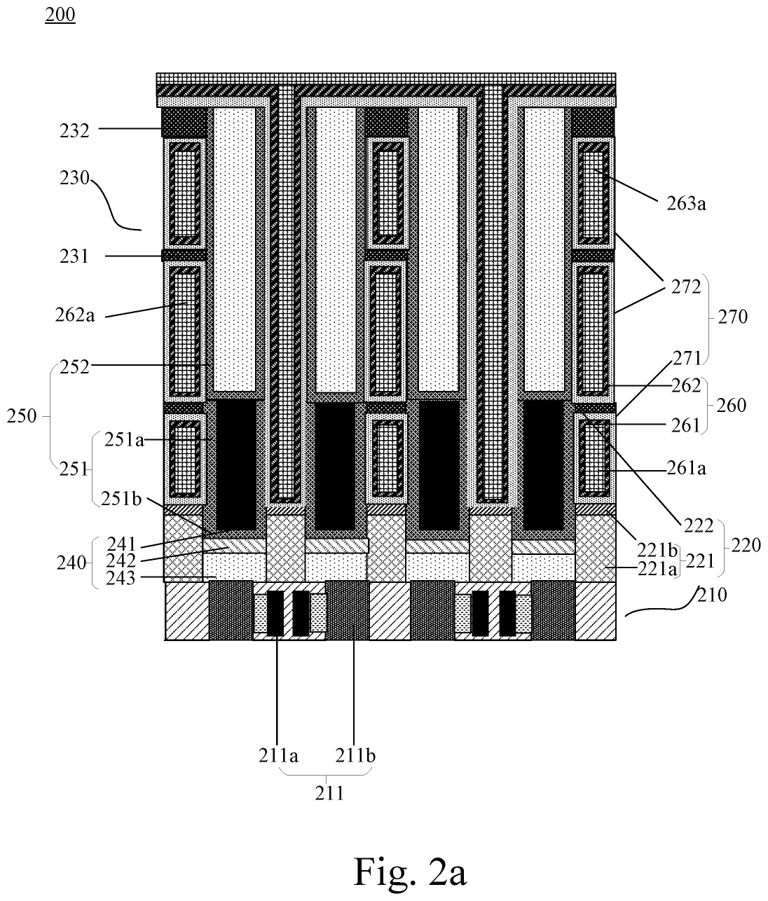

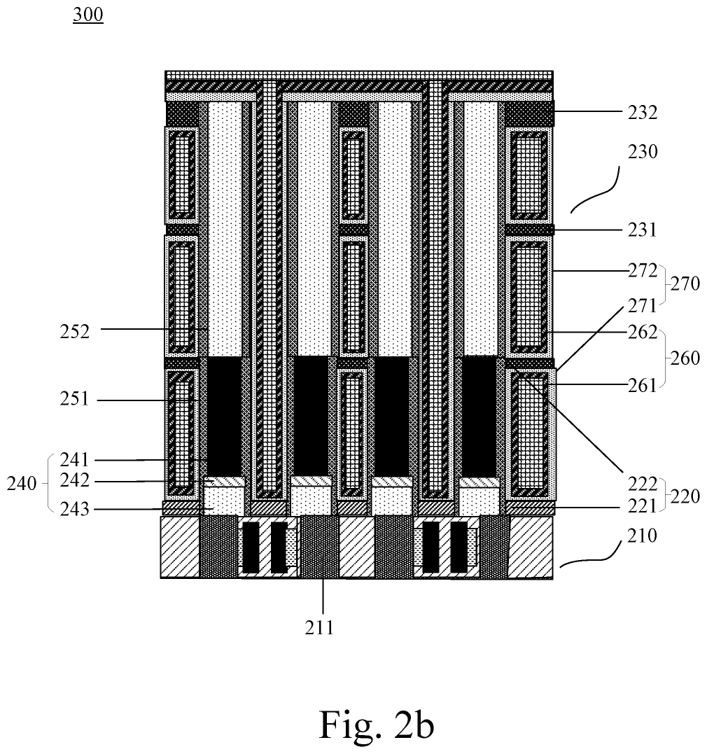

FIG. 2a is a sectional diagram I of a memory 200, according to an implementation of the present disclosure. Referring to FIG. 2a, the memory 200 may include one or more of the following. For example, the memory 200 may include a first semiconductor structure 210 including a vertical transistor 211. The memory 200 may include a first insulating structure 220 and a second insulating structure 230 stacked in turn on the first semiconductor structure 210. The memory 200 may include a contact structure 240 penetrating through the first insulating structure 220 and connected with the semiconductor body 211b of the vertical transistor. The memory 200 may include a first electrode structure 250 including a first electrode layer 251 penetrating through at least a part of the first insulating structure 220 and a second electrode layer 252 penetrating through the second insulating structure 230. The first electrode layer 251 may cover a sidewall of at least part of contact structure 240 and may be connected with the contact structure 240. The second electrode layer 252 may be connected with the first electrode layer 251. The memory 200 may include a second electrode structure 260 including a first part 261 in the first insulating structure 220 and a second part 262 in the second insulating structure 230. The first part 261 may cover a sidewall of part of the first electrode layer 251. The second part 262 may cover a sidewall of part of the second electrode layer 252. The memory 200 may include a capacitor dielectric layer 270 between the first electrode structure 250 and the second electrode structure 260.

The memory 200 includes a memory cell array and a peripheral circuit coupled with the memory cell array and configured to control logic operations such as write or read of the memory cell array. The memory 200 may include, but is not limited to, DRAM and implementations of the present disclosure will be described with an example in which the memory 200 is DRAM.

The memory cell array includes a plurality of memory cells each including a storage node (SN) and a transistor. A storage node represents an electronic element for storing data in the memory. For example, in DRAM, the storage node may be a capacitor. In some implementations, the memory cell further includes a storage node contact (SNC) for implementing connection between the storage node and the transistor and reducing the contact resistance between the storage node and the transistor, thereby improving the electrical performance of the memory.

The vertical transistor 211 includes a semiconductor body 211b extending in the thickness direction of the first semiconductor structure 210. The two ends of the semiconductor body 211b are provided with source and drain respectively that may be doped with a P-type dopant (e.g., such as Boron or Gallium) or an N-type dopant (e.g., such as Phosphorus or Arsenic). In the thickness direction of the first semiconductor structure 210, one or more channels (not shown) of the vertical transistor 211 may be disposed in the semiconductor body 211b between the source and the drain. The semiconductor body 211b may be at least partially surrounded by a gate 211a. A gate dielectric layer may be located between the gate 211a and the channel. Shallow trench isolations may be provided between adjacent vertical transistors 211. In some implementations, the semiconductor body 211b may be connected with a bit line (not shown) that is on a side of the semiconductor body 211b away from the first electrode structure 250. In some implementations, the semiconductor body 211b may be connected with the bit line via a bit line contact structure (not shown) located between the semiconductor body 211b and the bit line.

On the plane perpendicular to the thickness direction of the first semiconductor structure 210, the cross-sectional shape of the semiconductor body 211b may be rectangular, trapezoidal, circular, etc., by way of example and not limitation. The cross-sectional shape may be selected according to use-case scenario and is not limited particularly in the present disclosure.

The vertical transistor 211 may include a single gate transistor or a multi-gate transistor. The multi-gate transistor may include a gate-all-around transistor, a tri-gate transistor, or a dual-gate transistor. It is to be noted that multi-gate transistor may have a large gate controlling area to realize a better channel control with a small sub-threshold swing, namely improving the controlling capability of the gate over the channel.

The first insulating structure 220 is located between the first semiconductor structure 210 and the second insulating structure 230. The first insulating structure 220 and the second insulating structure 230 may each include a single insulating film or a plurality of insulating films. The implementations of the present disclosure will be described with an example in which each of the first insulating structure 220 and the second insulating structure 230 includes a plurality of insulating films. Description of the first insulating structure 220 and the second insulating structure 230 will be presented below.

The first end of the contact structure 240 may be connected with the semiconductor body 211b of the vertical transistor 211. The second end of the contact structure 240 may be exposed from the surface of the first insulating structure 220 away from the first semiconductor structure 210. The first end and second end of the contact structure 240 may be disposed oppositely in the thickness direction of the first semiconductor structure 210. The material of the contact structure 240 may include at least one of polysilicon, doped polysilicon, metal, and metal silicide, for example.

The first electrode structure 250 may include a first electrode layer 251 and a second electrode layer 252. In some implementations, the first electrode layer 251 may penetrate through part of the first insulating structure 220. A bottom of the first electrode layer 251 is located in the first insulating structure 220. The first electrode layer 251 may cover a sidewall of part of the contact structure 240, as shown in FIG. 2a.

The second electrode structure 260 may include a first part 261 and a second part 262. The first part 261 may cover a sidewall of part of the first electrode layer 251. The second part 262 may cover a sidewall of part of the second electrode layer 252, as shown in FIG. 2a.

The capacitor dielectric layer 270 may include a first sub-capacitor dielectric layer 271 between the first electrode layer 251 and the first part 261 and a second sub-capacitor dielectric layer 272 between the second electrode layer 252 and the second part 262.

Materials of the first electrode structure 250 and the second electrode structure 260 include conductive materials, e.g., such as at least one of semiconductor material (e.g., polysilicon, doped polysilicon etc.), metal (e.g., tungsten, titanium etc.), metal nitride (e.g., tungsten nitride, titanium nitride, tantalum nitride etc.) and metal silicide (e.g., titanium silicide, nickel silicide, titanium siliconitride etc.). Implementations of the present disclosure are described with an example in which the materials of the first electrode structure 250 and the second electrode structure 260 include titanium nitride.

The material of the capacitor dielectric layer 270 may include a capacitor dielectric material such as at least one of low dielectric constant material (e.g., silicon oxide etc.) and high dielectric constant material (e.g., aluminum oxide etc.).

In some implementations, the first electrode structure 250, the capacitor dielectric layer 270, and the second electrode structure 260 constitute a storage node in which the first electrode structure 250 and the second electrode structure 260 serve as the bottom electrode and top electrode respectively, and the contact structure 240 serves as the storage node contact.

In some implementations, in the thickness direction of the first semiconductor structure 210, the size of the first electrode structure 250 may be greater than the size of the second insulating structure 230 and smaller than or equal to the sum of the sizes of the first insulating structure 220 and the second insulating structure 230, which facilitates increasing the feature size of the first electrode structure 250. In the thickness direction of the first semiconductor structure 210, the size of the second electrode structure 260 may be greater than the size of the second insulating structure 230 and smaller than the sum of the sizes of the first insulating structure 220 and the second insulating structure 230, which facilitates increasing the feature size of the second electrode structure 260, thereby increasing the effective direct-facing area between the first electrode structure 250 and the second electrode structure 260.

In an implementation of the present disclosure, it may be possible to increase the feature size of the first electrode structure by providing a first electrode layer penetrating through at least part of a first insulating structure and a second electrode layer penetrating through the second insulating structure. It may be possible to increase the feature size of the second electrode structure by providing the first part covering sidewall of part of the first electrode layer and the second part covering sidewall of par of the second electrode layer, such that the effective direct-facing area between the first electrode structure and the second electrode structure is increased, which facilitates increasing the capacitance value of the capacitor.

In some implementations, the first insulating structure 220 may include a first insulating layer 221 and a first support layer 222 stacked in turn on the first semiconductor structure 210. The first insulating layer 221 may be disposed as being spaced apart from the first support layer 222 and the first part 261 is located between the first insulating layer 221 and the first support layer 222. Here, the first insulating layer 221 may include a first sub-insulating layer 221a and a second sub-insulating layer 221b located in turn on the first semiconductor structure 210.

In some implementations, the contact structure 240 over the first insulating layer 221, the first electrode layer 251 over the first insulating layer 221, the second electrode layer 252, the second electrode structure 260 and the capacitor dielectric layer 270 may constitute a storage node, in which the contact structure 240 over the first insulating layer 221, the first electrode layer 251 over the first insulating layer 221 and the second electrode layer 252 serve as the bottom electrode, the second electrode structure 260 serves as the top electrode, and the contact structure 240 in the first insulating layer 221 and the first electrode layer 251 constitute the storage node contact.

The material of the first insulating layer 221 may include an insulating material, e.g., such as at least one of silicon oxide, silicon nitride, silicon oxynitride, silicon boronitride, silicon nitridecarbide, etc. The material of the first support layer 222 may include at least one of, e.g., carbon nitride, silicon nitride, or carbide. In some implementations, the first insulating layer 221 may include a composite film formed of a plurality of films. In other implementations, the first insulating layer 221 may include a single film, which is not particularly limited in implementations of the present disclosure.

In some implementations, the memory 200 further includes a first fill layer 261a between the first insulating layer 221 and the first support layer 222. In the interval between the first insulating layer 221 and the first support layer 222, a first sub-capacitor dielectric layer 271, a first part 261 and a first fill layer 261a may be disposed in turn in the direction from radial outward of the interval to radial inward of the interval. The first fill layer 261a fills and covers the first side of the first part, and the second side of the first part 261 covers the first sub-capacitor dielectric layer 271. Here, the material of the first fill layer 261a may include polysilicon or silicon germanium, for example.

In an implementation of the present disclosure, by providing the first insulating structure including the first insulating layer and the first support layer disposed with interval, it may be possible to dispose the first part of the second electrode structure in the interval between the first insulating layer and the first support layer, thereby increasing the feature size of the second electrode structure and in turn increasing the effective direct-facing area between the first electrode structure and the second electrode structure, which facilitates increasing the capacitance value of the capacitor.

In some implementations, the contact structure 240 may include a metal layer 241 and a semiconductor layer 243. The metal layer 241 may penetrate through the first support layer 222 and extends into the first insulating layer 221. The semiconductor layer 243 may be located between the semiconductor body 211b and the metal layer 241.

The first electrode layer 251 may include a first sub-electrode layer 251a located over the semiconductor layer 243 and covering sidewall of the metal layer 241.

The first end of the metal layer 241 is located in the first insulating layer 221, the second end of the metal layer 241 may be exposed from the surface of the first support layer 222 away from the first insulating layer 221. In the thickness direction of the first semiconductor structure 210, the size of the metal layer 241 may be greater than the sum of the size of the first support layer 222 and the size of the interval and smaller than the size of the first insulating layer 221. The size of the semiconductor layer 243 may be smaller than the size of the first insulating layer 221. In some implementations, the first end of the metal layer 241 may be connected with the semiconductor layer 243, and the second end of the metal layer 241 may be connected with the second electrode layer 252.

The first sub-electrode layer 251a may cover the sidewall of the metal layer 241. In some implementations, the orthographic projection of the metal layer 241 may be a circle or an oval, and the first sub-electrode layer 251a may surround the metal layer 241.

The material of the metal layer 241 may include a conductive material, e.g., such as tungsten, copper or aluminum; and the material of the semiconductor layer 243 may include polysilicon or doped polysilicon, for example.

In an implementation of the present disclosure, providing the first sub-electrode layer to cover the sidewall of the metal layer facilitates increasing the feature size of the first electrode layer, thereby increasing the feature size of the first electrode structure; and the second electrode structure may be provided to cover the first electrode structure, thereby also increasing the feature size of the second electrode structure. Hence, the effective direct-facing area between the first electrode structure and the second electrode structure may be increased, which facilitates increasing the capacitance value of the capacitor.

In some implementations, the first electrode layer 251 may further include a second sub-electrode layer 251b located between the semiconductor layer 243 and the metal layer 241. Here, the second sub-electrode layer 251b may cover bottom of the metal layer 241, and the second sub-electrode layer 251b may be connected with the first sub-electrode layer 251a.

FIG. 2b is a sectional diagram II of a memory 300 illustrated according to an implementation of the present disclosure. Referring to FIG. 2b, the contact structure 240 may include a metal layer 241 and a semiconductor layer 243. The metal layer 241 may penetrate through the first support layer 222 and extend to between the first insulating layer 221 and the first support layer 222; and the semiconductor layer 243 may be located between the semiconductor body 211b and the metal layer 241.

The first electrode layer 251 may be located over the first semiconductor structure 210 and may cover a sidewalls of the semiconductor layer 243 and the metal layer 241.

The first end of the metal layer 241 may be located between the first insulating layer 221 and the first support layer 222. The second end of the metal layer 241 may be exposed from the surface of the first support layer 222 away from the first insulating layer 221. In the thickness direction of the first semiconductor structure 210, the size of the metal layer 241 may be smaller than the sum of the size of the first support layer 222 and the size of the interval. The size of the semiconductor layer 243 may be greater than the size of the first insulating layer 221. The first end of the semiconductor layer 243 may be connected with the semiconductor body 211b. The second end of the semiconductor layer 243 may be located in the interval between the first insulating layer 221 and the first support layer 222.

In some implementations, the first electrode layer 251 may penetrate through the first insulating structure 220. A bottom of the first electrode layer 251 may be flush with the surface of the first insulating structure 220 close to the first semiconductor structure 210. The first electrode layer 251 may cover a sidewall of the contact structure 240, as shown in FIG. 2b.

In an implementation of the present disclosure, by providing the first electrode layer to penetrate through the first insulating layer and cover the sidewall of the contact structure, in the thickness direction of the first semiconductor structure, the size of the first electrode structure may be equal to the sum of the sizes of the first insulating structure and the second insulating structure, which facilitates further increasing the size of the first electrode structure. Here, the first part may cover a sidewall of the first electrode layer between the first insulating layer and the first support layer, which facilitates further increasing the feature size of the second electrode structure and in turn further increasing the effective direct-facing area between the first electrode structure and the second electrode structure, thereby increasing the capacitance value of the capacitor.

In some implementations, referring to FIG. 2a or 2b, the contact structure 240 may include a connection layer 242 located between the semiconductor layer 243 and the metal layer 241. The material of the connection layer 242 may include metal silicide such as cobalt silicide, titanium silicide, or the like. The connection layer 242 may be configured to reduce the contact resistance between the semiconductor layer 243 and the metal layer 241 and improve the electrical performance of the memory.

In some implementations, referring to FIG. 2a, the second sub-electrode layer 251b may be located between the connection layer 242 and the metal layer 241. In the thickness direction of the first semiconductor structure 210, the semiconductor layer 243, the connection layer 242, the second sub-electrode layer 251b and the metal layer 241 may be connected in turn. Of course, in some implementations, it may be possible to omit the second sub-electrode layer 251b between the connection layer 242 and the metal layer 241. In the thickness direction of the first semiconductor structure 210, the semiconductor layer 243, the connection layer 242, and the metal layer 241 may be connected in turn, as shown in FIG. 2b. This is not particularly limited in the present disclosure and may be selected by those skilled in the art according to practical demands.

In some implementations, referring to FIG. 2a, the second insulating structure 230 may include a second support layer 231. The second support layer 231 may be disposed as being spaced apart from the first insulating structure 220; and the second part 262 may be located between the first insulating structure 220 and the second support layer 231.

In some implementations, referring to FIG. 2a, the memory 200 may further include a second fill layer 262a between the first support layer 222 and the second support layer 231. In the interval between the first insulating layer 220 and the second support layer 231, the second sub-capacitor dielectric layer 272, the second part 262, and the second fill layer 262a may be disposed in turn in the direction from radial outward of the interval to radial inward of the interval. The second fill layer 262a may fill and cover the first side of the second part 262, and the second side of the second part 262 covers the second sub-capacitor dielectric layer 272. Here, the material of the second fill layer 262a includes polysilicon or silicon germanium. The material of the second fill layer 262a and the material of the first fill layer 261a may be the same or different, which is not particularly limited in the present disclosure.

In some implementations, referring to FIG. 2a, the first insulating layer 221, the first part 261, the first support layer 222, the second part 262 and the second support layer 231 may be disposed in turn in the thickness direction of the first semiconductor structure 210.

The material of the second support layer 231 may include at least one of carbon nitride, silicon nitride or carbide. The material of the second support layer 231 and the material of the first support layer 222 may be the same or different, without limitation.

In some implementations, the first end of the second electrode layer 252 may be connected with the first electrode layer 251. The second end of the second electrode layer 252 may be exposed from the surface of the second support layer 231 away from the first insulating structure 220. The second part 262 may cover a sidewall of the second electrode layer 252 between the first support layer 222 and the second support layer 231. That is, the second part 262 may cover a sidewall of part of the second electrode layer 252.

In some implementations, the first end of the second electrode layer 252 may also be connected with the contact structure 240. As shown in FIG. 2a, the cross section of the second electrode layer 252 is of “U” shape.

In an implementation of the present disclosure, by providing the second support layer disposed as being spaced apart from the first insulating structure, it may be possible to further increase the size of the second electrode layer, thereby increasing the feature size of the first electrode structure. The second part may cover the sidewall of the second electrode layer between the first insulating structure and the second support layer, which further increases the feature size of the second electrode structure. This increases the effective direct-facing area between the first electrode structure and the second electrode structure, thereby increasing the capacitance value of the capacitor.

In some implementations, referring to FIG. 2a, the second insulating structure 230 further includes a third support layer 232. The third support layer 232 may be disposed as being spaced apart from second support layer 231; and the second part 262 may be located between the second support layer 231 and the third support layer 232.

In some implementations, referring to FIG. 2a, the memory 200 may further include a third fill layer 263a between the second support layer 231 and the third support layer 232. The capacitor dielectric layer 270 may further include the second sub-capacitor dielectric layer 272 between the second support layer 231 and the third support layer 232. The second electrode structure 260 may further include the second part 262 between the second support layer 231 and the third support layer 232. In the interval between the second support layer 231 and the third support layer 232, the second sub-capacitor dielectric layer 272, the second part 262, and the third fill layer 263a may be disposed in turn in the direction from radial outward of the interval to radial inward of the interval. The third fill layer 263a may fill and cover the first side of the second part 262; and the second side of the second part 262 may cover the second sub-capacitor dielectric layer 272. Here, the material of the third fill layer 263a includes polysilicon or silicon germanium.

In some implementations, referring to FIG. 2a, the first insulating layer 221, the first part 261, the first support layer 222, the second part 262, the second support layer 231, the second part 262, and the third support layer 232 may be disposed in turn in the thickness direction of the first semiconductor structure 210.

The material of the third support layer 232 may include at least one of carbon nitride, silicon nitride, or carbide. The materials of at least two of the first support layer 222, the second support layer 231, and the third support layer 232 may be the same or different, without limitation.

In some implementations, the first end of the second electrode layer 252 may be connected with the first electrode layer 251. The second end of the second electrode layer 252 may be exposed from the surface of the third support layer 232 away from the second support layer 231. The second part 262 may cover a sidewall of the second electrode layer 252 between the first support layer 222 and the second support layer 231 and a sidewall of the second electrode layer 252 between the second support layer 231 and the third support layer 232. That is, the second part 262 may cover a sidewall of part of the second electrode layer 252.

In an implementation of the present disclosure, by providing the third support layer disposed as being spaced apart from the second support layer, it may be possible to further increase the size of the second electrode layer, thereby increasing the feature size of the first electrode structure; and the second part may cover the sidewall of the second electrode layer between the first support layer and the second support layer and the sidewall of the second electrode layer between the second support layer and the third support layer. This may further increase the feature size of the second electrode structure, which in turn increases the effective direct-facing area between the first electrode structure and the second electrode structure, thereby increasing the capacitance value of the capacitor.

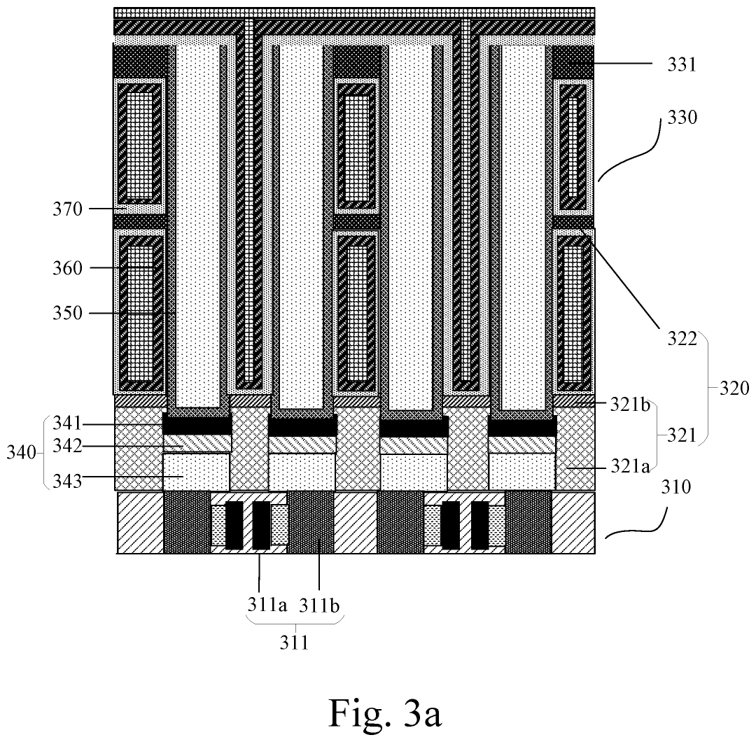

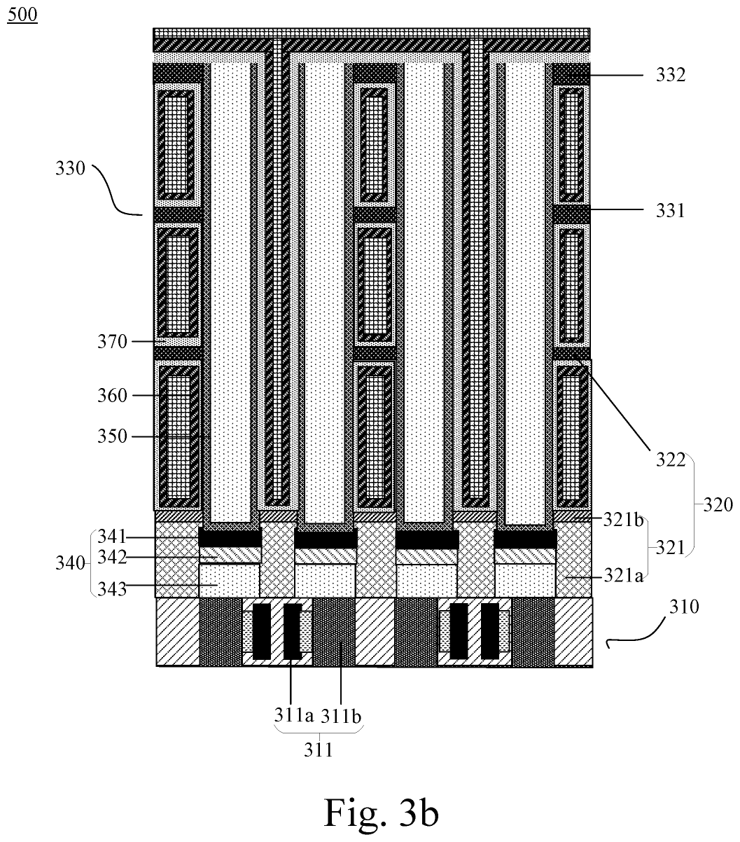

FIG. 3a is a sectional diagram III of a memory 400, according to an implementation of the present disclosure. A first semiconductor structure 310, a vertical transistor 311, a first insulating structure 320, a second insulating structure 330, a second electrode structure 360, and a capacitor dielectric layer 370 in FIG. 3a may be similar to the first semiconductor structure 210, the vertical transistor 211, the first insulating structure 220, the second insulating structure 230, the second electrode structure 260, and the capacitor dielectric layer 270 illustrated in the above-described implementations, and will not be further described. What is different from FIG. 2 is that a contact structure 340 is in a first insulating layer 321 and connected with a semiconductor body 311b of the vertical transistor 311, the first electrode structure 350 penetrates through the second insulating structure 330 and at least part of the first insulating structure 320, and the contact surface between the first electrode structure 350 and the contact structure 340 is in the first insulating layer 321.

In some implementations, referring to FIG. 3a, the first insulating structure 320 and the second insulating structure 330 may be disposed in turn in the thickness direction of the first semiconductor structure 310. The first insulating structure 320 may include a first insulating layer 321 and a first support layer 322 disposed as being spaced apart from each other. The second insulating structure 330 may include a second support layer 331 disposed as being spaced apart from the first insulating structure 320. The first electrode structure 350 may penetrate through the second insulating structure 330 and part of the first insulating structure 320. Here, the first electrode structure 350 penetrating through the second insulating structure 330 may include penetrating through the second support layer 331. The contact structure 340 may be smaller than the size of the first insulating layer 321 and may be located in the first insulating layer 321. The first end of the contact structure 340 may be connected with the semiconductor body 311b and the second end of the contact structure 340 is connected with the first electrode structure 350. The connection surface between the first electrode structure 350 and the contact structure 340 may be in the first insulating layer 321. The second electrode structure 360 may cover part of the first electrode structure 350. The capacitor dielectric layer 370 may be between the first electrode structure 350 and the second electrode structure 360.

It is to be noted that the first electrode structure 350 penetrating through at least part of the first insulating structure 320 and having a contact surface with the contact structure 340 in the first insulating layer 321 facilitates an increase in the feature size of the first electrode structure 350. This may increase the effective direct-facing area between the first electrode structure 350 and the second electrode structure 360 and increase the capacitance value of the capacitor.

FIG. 3b is a sectional diagram IV of a memory 500, according to an implementation of the present disclosure. Referring to FIG. 3b, in the thickness direction of the first semiconductor structure 310, the second insulating structure 330 may further include a third support layer 332 disposed as being spaced apart from the second support layer 331, the first electrode structure 350 may penetrate through the second insulating structure 330 and part of the first insulating structure 320. The first electrode structure 350 penetrating through the second insulating structure 330 may include penetrating through the third support layer 332 and the second support layer 331. The contact structure 340 may be smaller in size than the first insulating layer 321 and may be located in the first insulating layer 321. The first end of the contact structure 340 may be connected with the semiconductor body 311b and the second end of the contact structure 340 may be connected with the first electrode structure 350. The connection surface between the first electrode structure 350 and the contact structure 340 may be in the first insulating layer 321. The second electrode structure 360 may cover part of the first electrode structure 350, and the capacitor dielectric layer 370 may be between the first electrode structure 350 and the second electrode structure 360. Providing the first electrode structure to penetrate through the third support layer may facilitate an increase in the feature size of the first electrode structure. This may increase the effective direct-facing area between the first electrode structure and the second electrode structure, and increase the capacitance value of the capacitor.

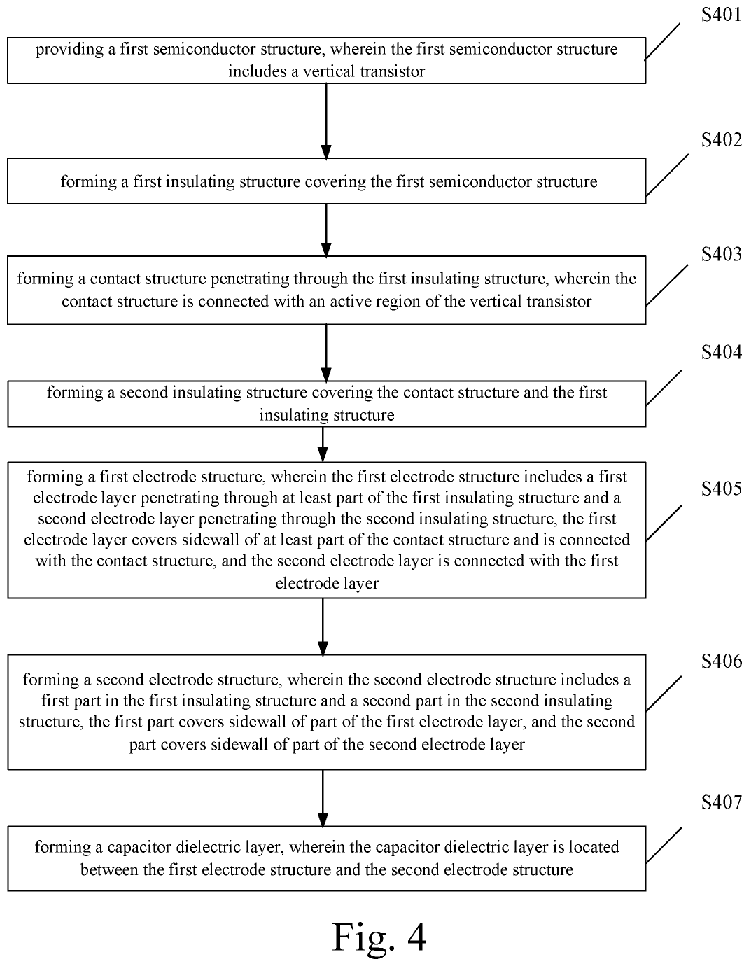

FIG. 4 is a flow chart of a method of fabricating a memory, according to an implementation of the present disclosure. Referring to FIG. 4, the method may include one or more of the following operations.

For example, at operation S401, the method may include providing a first semiconductor structure. The first semiconductor structure includes a vertical transistor.

At operation S402, the method may include forming a first insulating structure covering the first semiconductor structure.

At operation S403, the method may include forming a contact structure penetrating through the first insulating structure. The contact structure may be connected with a semiconductor body of the vertical transistor.

At operation S404, the method may include forming a second insulating structure covering the contact structure and the first insulating structure.

At operation S405, the method forming a first electrode structure. The first electrode structure may include a first electrode layer penetrating through at least part of the first insulating structure and a second electrode layer penetrating through the second insulating structure. The first electrode layer may cover a sidewall of at least part of the contact structure and may be connected with the contact structure. The second electrode layer may be connected with the first electrode layer.

At operation S406, the method may include forming a second electrode structure. The second electrode structure may include a first part in the first insulating structure and a second part in the second insulating structure. The first part may cover a sidewall of part of the first electrode layer, and the second part may cover a sidewall of part of the second electrode layer.

At operation S407, the method may include forming a capacitor dielectric layer. The capacitor dielectric layer may be between the first electrode structure and the second electrode structure.

It is to be noted that the operations shown in FIG. 4 are not exclusive and other operations may be performed before, after or between any operations in the illustrated operations. Operations shown in FIG. 4 may be adjusted in terms of order according to practical demands.

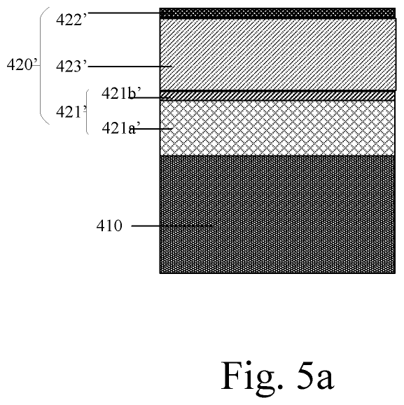

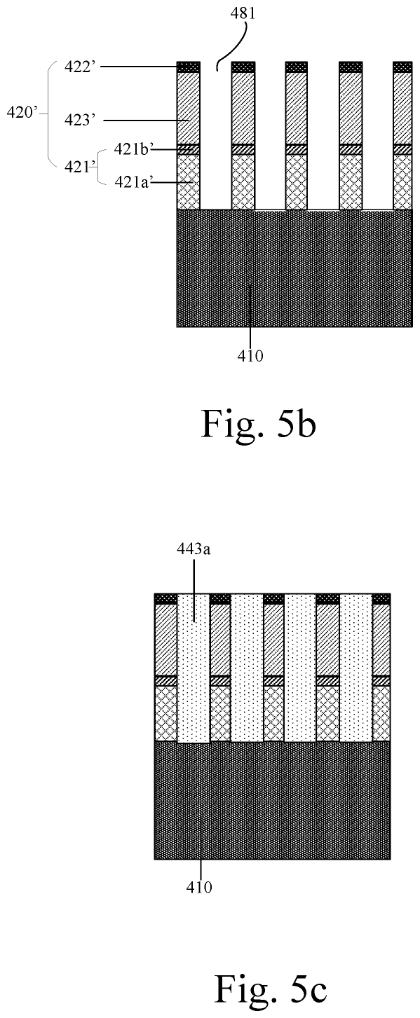

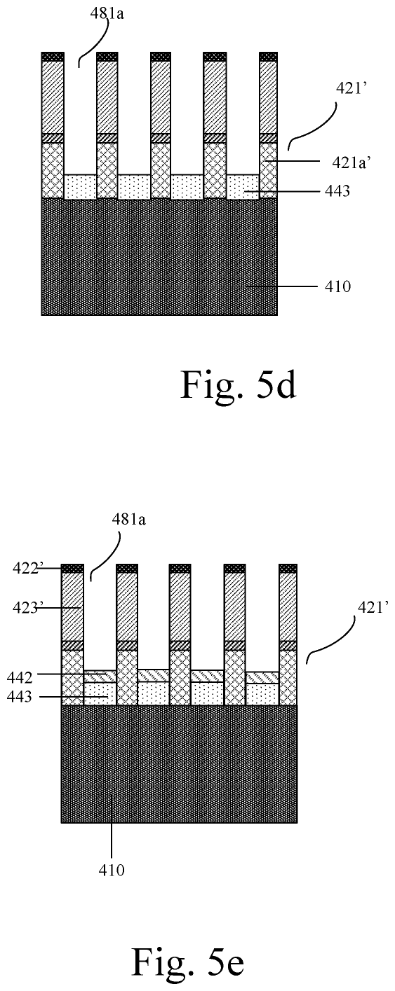

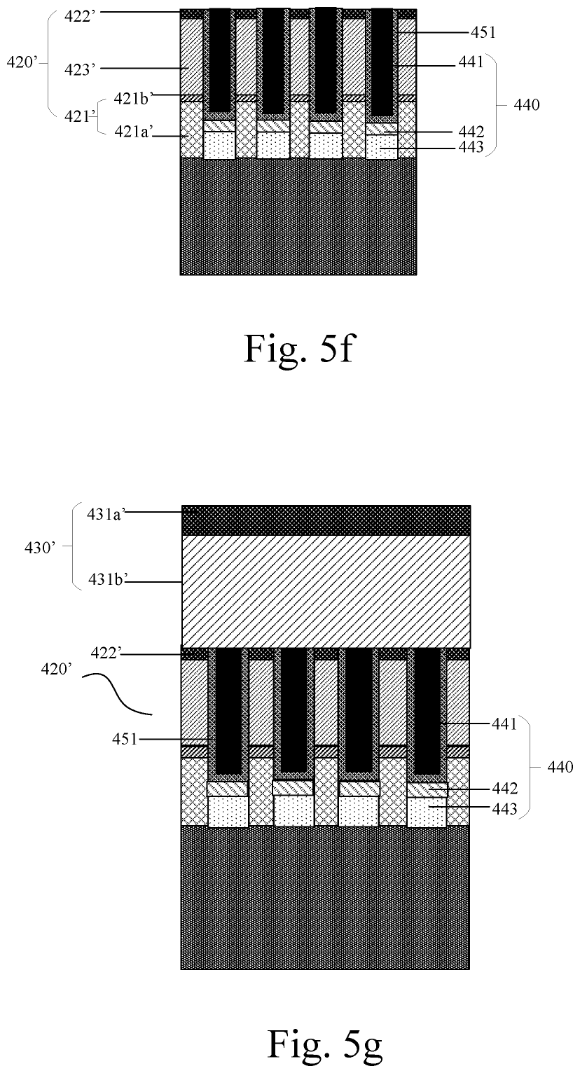

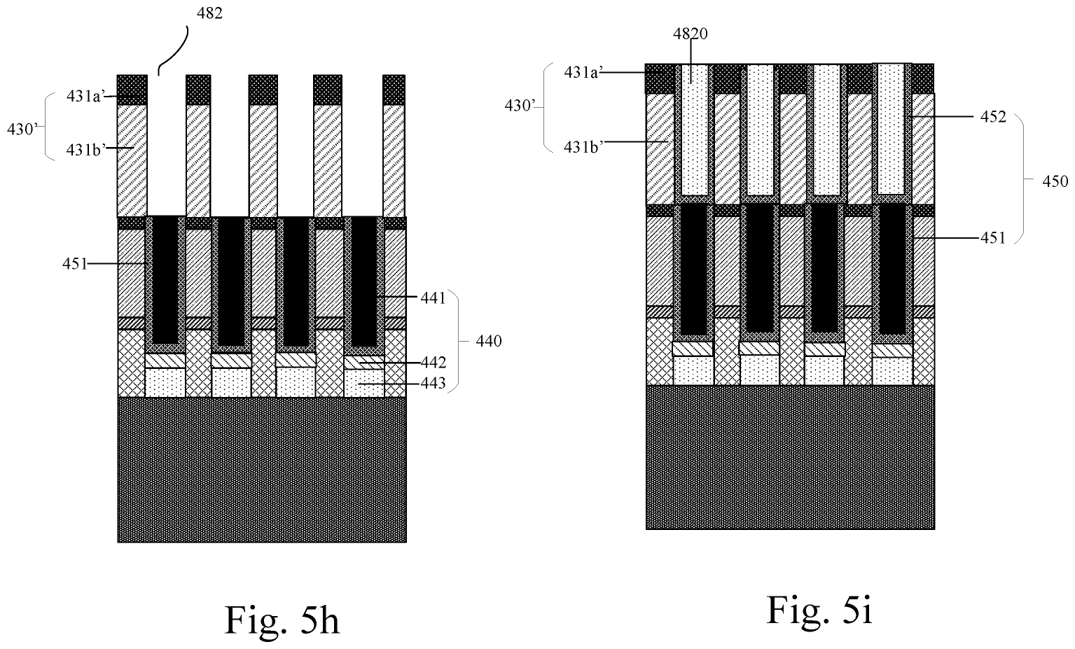

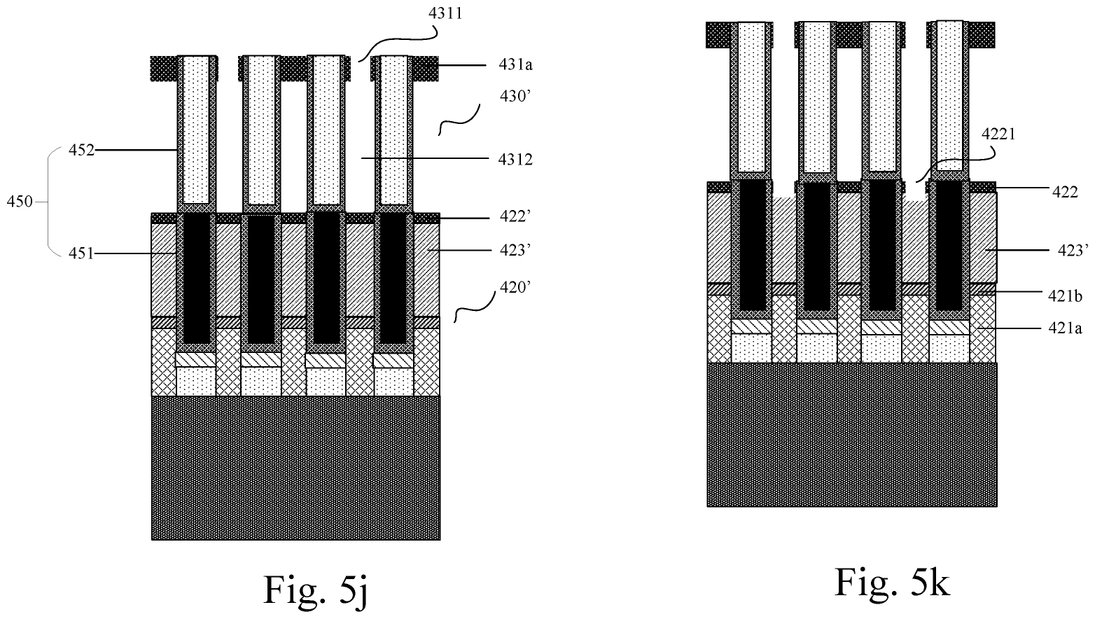

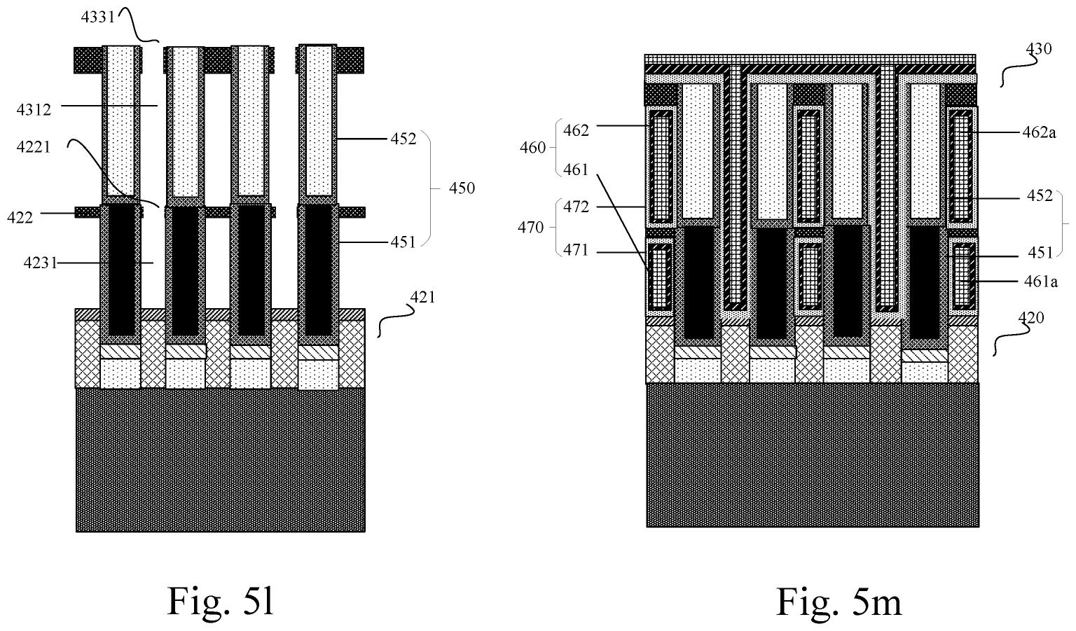

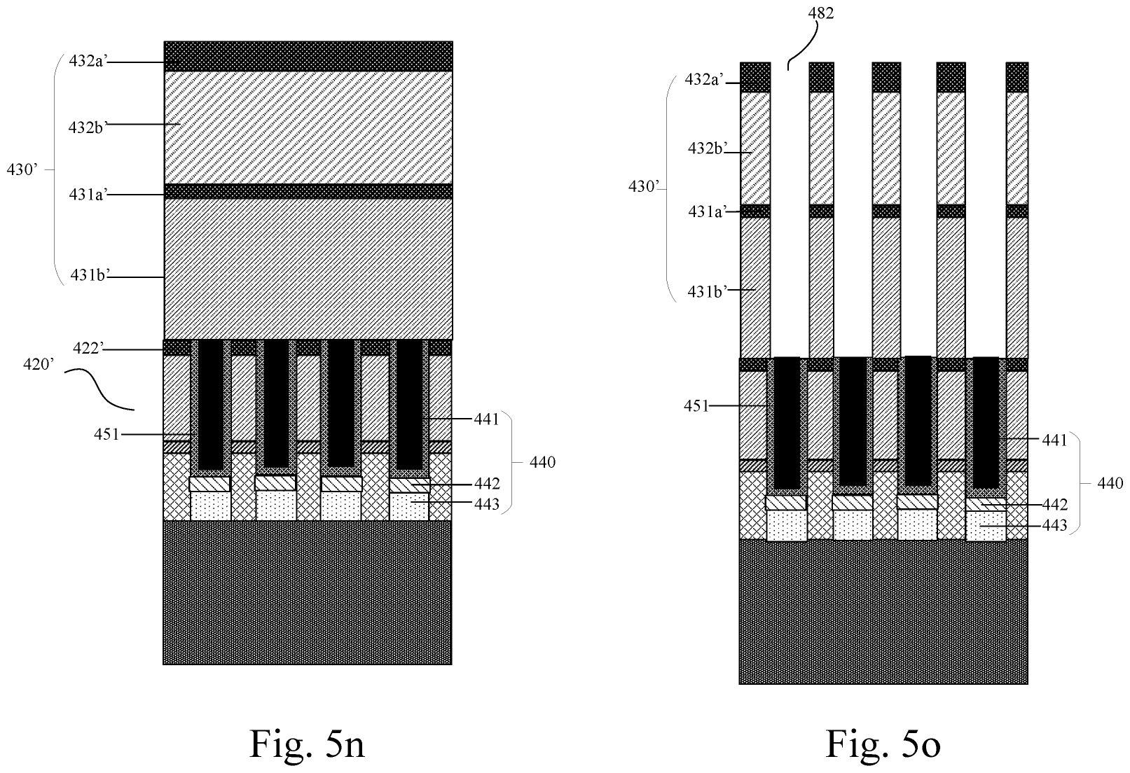

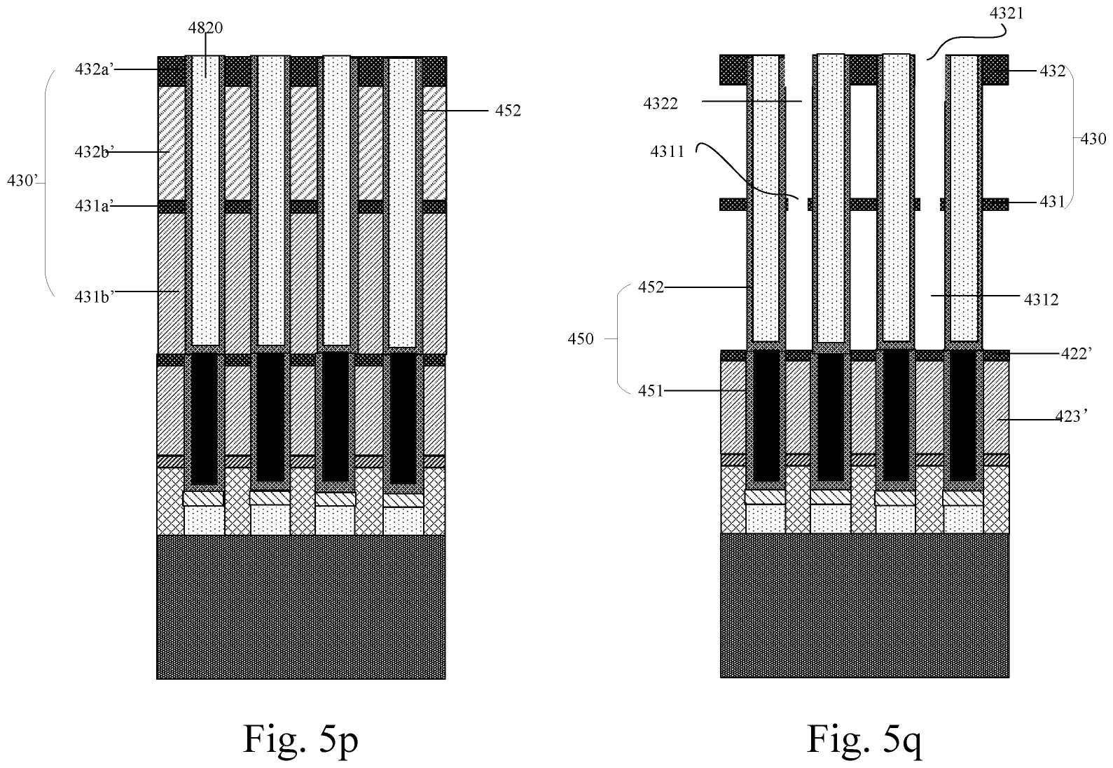

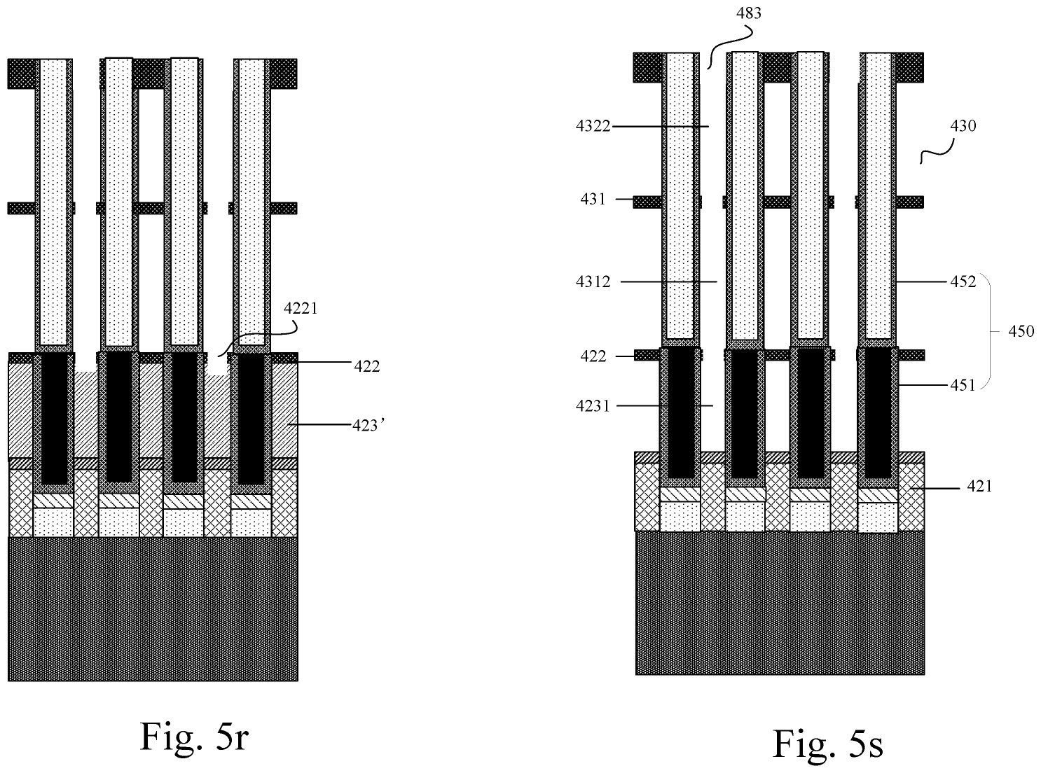

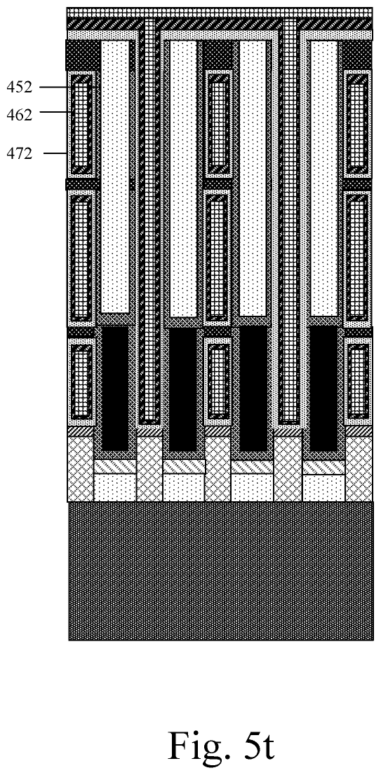

FIGS. 5a to 5t are diagram I of a fabrication process of a memory, according to an implementation of the present disclosure. The method of fabricating the memory provided by implementations of the present disclosure will be described in detail below in conjunction with FIGS. 4, 5a to 5t.

At operation S401, referring to FIG. 5a, a first semiconductor structure 410 is provided. The first semiconductor structure 410 may include a vertical transistor (not shown).

Example operations of providing the first semiconductor structure 410 may include, e.g., providing a substrate, and forming a semiconductor body over the substrate in the thickness direction of the first semiconductor structure 410. Here, the semiconductor body may be formed of the substrate (e.g., by etching or epitaxy). Here, the substrate not formed as semiconductor body may be removed in a subsequent process. Two ends of the semiconductor body are doped to form a source and a drain that may be doped with a P-type dopant (e.g., such as boron or gallium) or an N-type dopant (e.g., such as phosphorus and arsenic). A gate (not shown) is formed on at least one side of the semiconductor body. In the thickness direction of the first semiconductor structure 410, one or more channels (not shown) are formed between the source and drain of the semiconductor body. A gate dielectric layer (not shown) may be formed between the channels and the gate. The vertical transistor includes the gate and the semiconductor body. Shallow trench isolations (not shown) may be formed between adjacent vertical transistors. Here, it may be possible to form shallow trench isolations between adjacent semiconductor bodies by photolithography process, etching process, and film deposition process.

In some implementations, the gate may be formed on one side of the semiconductor body, then the vertical transistor is a single-gate transistor. In other implementations, gates may be formed on at least two sides of the semiconductor body; then, the vertical transistor is a multi-gate transistor, which includes a gate-all-around transistor, a tri-gate transistor, or a dual-gate transistor. It is to be noted that the multi-gate transistor may have a large gate controlling area to realize a better channel control with a small sub-threshold swing.

The material of the substrate includes elementary semiconductor material such as silicon, germanium, III-V compound semiconductor material, II-VI compound semiconductor material, organic semiconductors material, or other semiconductor material(s) known in the art. The material of the shallow trench isolation may include at least one of silicon oxide, silicon nitride or silicon oxynitride.

At operation S402, the first insulating structure covering the first semiconductor structure may be formed.

In some implementations, referring to FIG. 5a, the above-described fabrication method further includes forming a first insulating structure material layer 420′ covering the first semiconductor structure 410. The first insulating structure material layer 420′ may include a first insulating material layer 421′, a first sacrificial-material layer 423′, and a first support material layer 422′ stacked in turn. For example, the first insulating material layer 421′ covering the first semiconductor structure 410, the first sacrificial-material layer 423′, and the first support material layer 422′ may be formed in turn using a film deposition process.

Here, the first insulating structure material layer 420′ may be configured to form the first insulating structure 420 in a subsequent process. The first insulating material layer 421′ may be configured to form the first insulating layer 421 in a subsequent process. The first support material layer 422′ may be configured to form the first support layer 422 in a subsequent process. The first sacrificial-material layer 423′ may be removed in a subsequent process to form the second gap 4231. The material of the first sacrificial-material layer 423′ may include silicon oxide. Implementations of the present disclosure are described with an example in which the first sacrificial-material layer 423′ includes tetraethyl silicate (TEOS).

The material of the first insulating material layer 421′ may include an insulating material, e.g., such as at least one of silicon oxide, silicon nitride, silicon oxynitride, silicon boronitride, silicon nitridecarbide, etc. The material of the first support material layer 422′ may include at least one of carbon nitride, silicon nitride, or carbide.

In some implementations, the first insulating material layer 421′ may include a composite film formed of a plurality of films. In other implementations, the first insulating material layer 421′ may include a single film or multiple films, without limitation.

In some implementations, the above-described forming the first insulating material layer 421′ covering the first semiconductor structure 410 may include forming a first sub-insulating material layer 421a′ and a second sub-insulating material layer 421b′ covering the first semiconductor structure 410 in turn. The first sacrificial-material layer 423′ may cover the second sub-insulating material layer 421b′.

At operation S403 to operation S405, referring to FIGS. 5c to 5i, the contact structure 440 penetrating through the first insulating structure may be formed. The contact structure 440 may be connected with the semiconductor body of the vertical transistor. The second insulating structure covering the contact structure 440 and the first insulating structure may be formed. A first electrode structure 450 may be formed. The first electrode structure 450 may include a first electrode layer 451 penetrating through at least part of the first insulating structure and a second electrode layer 452 penetrating through the second insulating structure. The first electrode layer 451 may cover a sidewall of at least part of the contact structure 440 and is connected with the contact structure 440. The second electrode layer 452 may be connected with the first electrode layer 451.

In some implementations, referring to FIG. 5b, the above-described fabrication method further may include forming a first through hole 481 penetrating through the first insulating structure material layer 420′. A bottom of the first through hole 481 may expose the semiconductor body (not shown). Here, a remaining portion of the first insulating material layer 421′ may constitute the first insulating layer 421, a remaining portion of the first sub-insulating material layer 421a′ may constitute the first sub-insulating layer 421a, and a remaining portion of the second sub-insulating material layer 421b′ constitutes the second sub-insulating layer 421b.

In some implementations, referring to FIGS. 5b to 5f, the above-described operation S403 may include, e.g., forming a semiconductor layer 443 connected with the semiconductor body in the first through hole 481. The size of the semiconductor layer 443 may be smaller than the size of the first insulating material layer 421′ in the thickness direction of the first semiconductor structure 410. Operation S403 may include forming a metal layer 441 connected with the semiconductor layer 443 on the semiconductor layer 443. The contact structure 440 may include the semiconductor layer 443 and the metal layer 441.

In some implementations, referring to FIGS. 5e and 5f, the above-described operation S405 may include, after forming the semiconductor layer 443, forming a first sub-through hole 481a with the bottom exposing the semiconductor layer 443 based on the topography of the first through hole 481. Operation S405 may include forming a first electrode layer 451 covering sidewall and bottom of the first sub-through hole 481a.

The above-described forming the metal layer 441 on the semiconductor layer 443 may include forming the metal layer 441 in the first sub-through hole 481a formed with the first electrode layer 451.

In some implementations, referring to FIGS. 5c and 5d, a semiconductor material layer 443a may be deposited in the first through hole 481. A bottom of the semiconductor material layer 443a may be connected with the semiconductor body. In the thickness direction of the first semiconductor structure 410, the semiconductor material layer 443a may be etched until the size of the semiconductor material layer 443a is smaller than the size of the first insulating material layer 421′. A remaining portion of the semiconductor material layer 443a may constitute the semiconductor layer 443. In some implementations, referring to FIG. 5d, in the thickness direction of the first semiconductor structure 410, the size of the semiconductor layer 443 may be smaller than the size of the first sub-insulating material layer 421a′. Here, the material of the semiconductor material layer 443a may include polysilicon or doped polysilicon, for example.

In some implementations, referring to FIG. 5e, the above-described operation S403 may further include, after forming the semiconductor layer 443, forming a connection layer 442 on the semiconductor layer 443. The sum of sizes of the connection layer 442 and the semiconductor layer 443 may be smaller than the size of the first insulating material layer 421′ in the thickness direction of the first semiconductor structure 410. The material of the connection layer 442 may include metal silicide such as cobalt silicide or titanium silicide, for example. The connection layer 442 may be configured to reduce the contact resistance between the semiconductor layer 443 and the metal layer 441 and improve the electrical performance of the memory.

Referring to FIGS. 5e and 5f, after forming the semiconductor layer 443 and the connection layer 442, a remaining portion of the part of the first through hole 481 may constitute the first sub-through hole 481a; and the first electrode layer 45 covering the sidewall and bottom of the first sub-through hole 481a may be formed. The bottom of the first electrode layer 451 may be located in the first insulating material layer 421′. After forming the first electrode layer 451, a metal conductive material may be deposited in the first sub-through hole 481a to form the metal layer 441 with a first end located in the first insulating material layer 421′ and a second end exposed from the surface of the first support material layer 422′ away from the first insulating material layer 421′. In some implementations, the orthographic projection of the metal layer 441 is a circle or an oval; in the thickness direction of the first semiconductor structure 410, the size of the metal layer 441 may be greater than the sum of the sizes of the first support material layer 422′ and the first sacrificial-material layer 423′ and smaller than the size of the first insulating structure material layer 420′. The first electrode layer 451 may cover a sidewall and bottom of the metal layer 441.

Here, the material of the first electrode layer 451 include conductive materials, e.g., such as at least one of semiconductor material (e.g., polysilicon, doped polysilicon etc.), metal (e.g., tungsten, titanium etc.), metal nitride (e.g., tungsten nitride, titanium nitride, tantalum nitride etc.) and metal silicide (e.g., titanium silicide, nickel silicide, titanium siliconitride etc.). Implementations of the present disclosure are described with an example in which the materials of the first electrode layer 451 includes titanium nitride.

In some implementations, referring to FIG. 5g, the above-described fabrication method further includes forming a second insulating structure material layer 430′ covering the first insulating structure material layer 420′, the first electrode layer 451, and the contact structure 440. The second insulating structure material layer 430′ may include a second sacrificial-material layer 431b′ and a second support material layer 431a′ stacked in turn.

In some implementations, referring to FIG. 5g, forming the second insulating structure material layer 430′ may include forming the second sacrificial-material layer 431b′ and the second support material layer 431a′ in turn on the first insulating structure material layer 420′. Here, the second insulating structure material layer 430′ may be configured to form the second insulating structure 430 in a subsequent process. The second support material layer 431a′ may be configured to form the second support layer 431 in a subsequent process. The second sacrificial-material layer 431b′ will be removed in a subsequent process to form a first gap 4312.

The material of the second support material layer 431a′ may include at least one of carbon nitride, nitride or carbide. The materials of the second support material layer 431a′ and the first support material layer 422′ may be the same or different, without limitation.

In some implementations, referring to FIG. 5h, the above-described fabrication method further includes forming a second through hole 482 penetrating through the second insulating structure material layer 430′. A bottom of the second through hole 482 exposes the first electrode layer 451 and the contact structure 440.

In some implementations, referring to FIG. 5i, the above-described operation S405 may further include at least forming a second electrode layer 452 covering sidewall of the second through hole 482 and forming a second sub-through hole (not shown) based on the topography of the second through hole 482.

In some implementations, still referring to FIG. 5i, the above-described fabrication method further includes filling the second sub-through hole to form an electrode contact layer 4820.

In some implementations, the above-described at least forming the second electrode layer 452 covering the sidewall of the second through hole 482 may include forming the second electrode layer 452 covering the sidewall and bottom of the second through hole 482.

In some other implementations, the above-described at least forming the second electrode layer 452 covering the sidewall of the second through hole 482 may include forming the second electrode layer 452 covering the sidewall and bottom of the second through hole 482, and etching away the second electrode material layer covering the bottom of the second via 482. A remaining portion of the second electrode material layer may constitute the second electrode layer 452 covering the sidewall of the second through hole 482.

Here, it may be possible to form the second electrode layer 452 by atomic layer deposition process or plasma vapor process. The first end of the second electrode layer 452 may be connected with the first electrode layer 451 and the contact structure 440, and the second end of the second electrode layer 452 may be exposed from the surface of the second support material layer 431a′ away from the second sacrificial-material layer 431b′.

The material of the second electrode layer 452 may include conductive materials, e.g., such as at least one of semiconductor material (e.g., polysilicon, doped polysilicon etc.), metal (e.g., tungsten, titanium etc.), metal nitride (e.g., tungsten nitride, titanium nitride, tantalum nitride etc.), and metal silicide (e.g., titanium silicide, nickel silicide, titanium siliconitride etc.). The materials of the first electrode layer 451 and the second electrode layer 452 may be the same or different. Implementations of the present disclosure are described with an example in which the material of the second electrode layer 452 includes titanium nitride.

After forming the second electrode layer 452, a remaining portion of the part of the second through hole 482 may constitute the second sub-through hole in which an electrode contact material is filled to form the electrode contact layer 4820. The second electrode layer 452 may cover a sidewall and bottom of the electrode contact layer 4820. In other implementations, the second electrode layer 452 may cover the sidewall of the electrode contact layer 4820. The material of the electrode contact layer 4820 may include polysilicon or doped polysilicon, for example.

In some implementations, referring to FIGS. 5i to 5l, the memory may include a plurality of first electrode structures 450. The above-described method may further include forming a third through hole 483 penetrating through the second insulating structure material layer 430′, the first support material layer 422′, and the first sacrificial-material layer 423′. The third through hole 483 may be located between adjacent two first electrode structures 450; a sidewall of the third through hole 483 may expose part of the first electrode layer 451 and part of the second electrode layer 452; and a bottom of the third through hole 483 may expose the first insulating material layer 421′. Here, in the thickness direction of the first semiconductor structure 410, the first insulating structure material layer 420′ and the second insulating structure material layer 430′ are disposed in turn between adjacent two first electrode structures 450, and the third through hole 483 penetrating through the second insulating material layer 430′ includes penetrating through the second support material layer 431a′ and the second sacrificial-material layer 431b′.

In some implementations, referring to FIGS. 5i to 5l, forming the third through hole 483 penetrating through the second insulating structure 430′, the first support material layer 422′ and the first sacrificial-material layer 423′ may include etching down the second support material layer 431a′ according to a mask pattern to form a first opening 4311. A bottom of the first opening 4311 exposes the second sacrificial-material layer 431b′. A remaining portion of the second support material layer 431a′ constitutes the second support layer 431.

Still referring to FIGS. 5i to 5l, forming the third through hole 483 penetrating through the second insulating structure 430′, the first support material layer 422′ and the first sacrificial-material layer 423′ may include removing the second sacrificial-material layer 431b′ according to the first opening 4311 to form the first gap 4312. A sidewall of the first gap 4312 exposes part of the second electrode layer 452. A bottom of the first gap 4312 exposes the first support material layer 422′. The second insulating structure 430 includes the second support layer 431.

Still referring to FIGS. 5i to 5l, forming the third through hole 483 penetrating through the second insulating structure 430′, the first support material layer 422′ and the first sacrificial-material layer 423′ may include etching down the first support material layer 422′ according to the mask pattern to form a second opening 4221. A bottom of the second opening 4221 exposes the first sacrificial-material layer 423′. A remaining portion of the first support material layer 422′ constitutes the first support layer 422.

Still referring to FIGS. 5i to 5l, forming the third through hole 483 penetrating through the second insulating structure 430′, the first support material layer 422′ and the first sacrificial-material layer 423′ may include removing the first sacrificial-material layer 423′ according to the second opening 4221 to form a second gap 4231. A sidewall of the second gap 4231 exposes part of the first electrode layer 451. A bottom of the second gap 4231 exposes the first insulating material layer 421′. A remaining portion of the first insulating material layer 421′ constitutes the first insulating layer 421. The first insulating structure includes the first insulating layer 421 and the first support layer 422.

A mask structure covering the second support material layer 431a′ may be formed. The mask structure may be a single film or a composite film. The mask structure may include one of silicon oxide, silicon nitride, silicon oxynitride, amorphous carbon, spin-coated carbon, or combinations thereof. It may be possible to form a mask pattern in the mask structure by self-aligning process and etch down the second support material layer 431a′ according to the mask pattern to form the first opening 4311 exposing the second sacrificial-material layer 431b′ that can be subsequently removed via the first opening 4311. Here, a remaining portion of the second support material layer 431a′ constitutes the second support layer 431, as shown in FIG. 5j.

The second sacrificial-material layer 431b′ may be removed by wet etching to expose the first support material layer 422′, thereby forming the first gap 4312 exposing sidewall of the second electrode layer 452 between the second support layer 431 and the first support material layer 422′, as shown in FIG. 5j.

After removing the second sacrificial-material layer 431b′, the exposed first support material layer 422′ may be continuously etched down according to the mask pattern to form the second opening 4221 exposing the first sacrificial-material layer 423′ that may be removed via the second opening 4221 subsequently. Here, a remaining portion of the first support material layer 422′ constitutes the first support layer 422, as shown in FIG. 5k.

The first sacrificial-material layer 423′ may be removed by wet etching to expose the first insulating material layer 421′, thereby forming the second gap 4231 exposing sidewall of the first electrode layer 451 between the first support layer 422 and the first insulating material layer 421′. A remaining portion of the first insulating material layer 421′ constitutes the first insulating layer 421, as shown in FIG. 5l.

In some implementations, the etch-selectivity ratio of the second sacrificial-material layer may be smaller than the etch-selectivity ratio of the first sacrificial-material layer. Here, the materials of the first sacrificial-material layer and the second sacrificial-material layer may include silicon oxide, for example. Implementations of the present disclosure are described with an example in which the first sacrificial-material layer and the second sacrificial-material layer include tetraethyl silicate (TEOS).

In some implementations, the concentrations of phosphorus element and boron element doped in the first sacrificial-material layer are greater than the concentrations of phosphorus element and boron element doped in the second sacrificial-material layer such that while etching the first sacrificial-material layer and the second sacrificial-material layer, the closer to the first semiconductor structure, the higher the etch rate. This may adjust the perpendicularity of the sidewalls of the first gap and the second gap. In other implementations, the concentrations of phosphorus element and boron element doped in the first sacrificial-material layer are equal to the concentrations of phosphorus element and boron element doped in the second sacrificial-material layer such that while etching the first sacrificial-material layer and the second sacrificial-material layer, the etch rates are the same.

Referring to FIG. 5m, at operation S407, a capacitor dielectric layer 470 is formed. The capacitor dielectric layer 470 may be located between the first electrode structure 450 and a second electrode structure 460.

In some implementations, still referring to FIG. 5m, the above-described operation S407 may include forming a first sub-capacitor dielectric layer 471 covering the exposed first electrode layer 451. Operation S407 may also include forming a second sub-capacitor dielectric layer 472 covering the exposed second electrode layer 452. The capacitor dielectric layer 470 may include the first sub-capacitor dielectric layer 471 and the second sub-capacitor dielectric layer 472.

In some implementations, the above-described forming the first sub-capacitor dielectric layer 471 covering the exposed first electrode layer 451 may include forming the first sub-capacitor dielectric layer 471 in the second gap 4231; and the above-described forming the second sub-capacitor dielectric layer 472 covering the exposed second electrode layer 452 may include forming the second sub-capacitor dielectric layer 472 in the first gap 4312.

In some implementations, referring to FIG. 5m, a capacitor dielectric material is deposited in the first gap 4312 to form the second sub-capacitor dielectric layer 472, and a capacitor dielectric material is deposited in the second gap 4231 to form the first sub-capacitor dielectric layer 471. Here, the capacitor dielectric material includes at least one of low dielectric constant material such as silicon oxides and high dielectric constant material such as aluminum oxide.

In some implementations, the first gap 4312 is in communication with the second gap 4231, the formed first sub-capacitor dielectric layer 471 and second sub-capacitor dielectric layer 472 are connected. In other implementations, the first gap 4312 is not in communication with the second gap 4231. The formed first sub-capacitor dielectric layer 471 and second sub-capacitor dielectric layer 472 are separated by the first support layer. Here, the first sub-capacitor dielectric layer 471 and the second sub-capacitor dielectric layer 472 may be formed in the same process and may also be formed one after another in different processes, without limitation.

Referring to FIG. 5m, at operation S406, the second electrode structure 460 is formed. The second electrode structure 460 may include a first part 461 in the first insulating structure 420 and a second part 462 in the second insulating structure 430. The first part 461 may cover a sidewall of part of the first electrode layer 451, and the second part 462 may cover a sidewall of part of the second electrode layer 452.

In some implementations, referring to FIG. 5m, the above-described operation S406 may include forming the first part 461 covering the first sub-capacitor dielectric layer 471. Operation S406 may also include forming the second part 462 covering the second sub-capacitor dielectric layer 472.

In some implementations, the above-described forming the first part 461 covering the first sub-capacitor dielectric layer 471 may include forming the first part 461 in the second gap 4231 formed with the first sub-capacitor dielectric layer 471; and the above-described forming the second part 462 covering the second sub-capacitor dielectric layer 472 may include forming the second part 462 in the first gap 4312 formed with the second sub-capacitor dielectric layer 472.

In some implementations, still referring to FIG. 5m, a conductive material may be deposited on the first sub-capacitor dielectric layer 471 and the second sub-capacitor dielectric layer 472 respectively to form the first part 461 and the second part 462. The conductive material includes at least one of semiconductor material (e.g., polysilicon, doped polysilicon etc.), metal (e.g., tungsten, titanium etc.), metal nitride (e.g., tungsten nitride, titanium nitride, tantalum nitride etc.) and metal silicide (e.g., titanium silicide, nickel silicide, titanium siliconitride etc.). Implementations of the present disclosure are described with an example in which the material of the second electrode structure 460 includes titanium nitride.

In some implementations, the above-described fabrication method may further include forming a first fill layer 461a on a side of the first part 461 away from the first sub-capacitor dielectric layer 471 and a second fill layer 462a on a side of the second part 462 away from the second sub-capacitor dielectric layer 472. The materials of the first fill layer 461a and the second fill layer 462a may include polysilicon or silicon germanium, for example. The materials of the first fill layer 461a and the second fill layer 462a may be the same or different, without limitation.

In some implementations, referring to FIGS. 5n to 5s, the second insulating structure material layer 430′ may further include a third sacrificial-material layer 432b′ and a third support material layer 432a′ stacked in turn. The third sacrificial-material layer 432b′ may be located between the second support material layer 431a′ and the third support material layer 432a′.

The above-described forming the third through hole 483 penetrating through the second insulating structure material layer 430′, the first support material layer 422′, and the first sacrificial-material layer 423′ may include etching down the third support material layer 432a′ according to the mask pattern to form a third opening 4321. A bottom of the third opening 4321 exposes the third sacrificial-material layer 423b′; and a remaining portion of the third support material layer 432a′ constitutes the third support layer 432; and

The forming the third through hole 483 penetrating through the second insulating structure material layer 430′, the first support material layer 422′, and the first sacrificial-material layer 423′ may include removing the third sacrificial-material layer 432b′ according to the third opening 4321 to form a third gap 4322. A sidewall of the third gap 4322 exposes part of the second electrode layer 452. A bottom of the third gap 4322 exposes the second support material layer 431a′. The second insulating structure 430 may further include the third support layer 432.

Referring to FIG. 5n, forming the second insulating structure material layer 430′ may further include after forming the second support material layer 431a′, forming the third sacrificial-material layer 432b′ and the third support material layer 432a′ in turn on the second support material layer 431a′. Here, the methods for forming the third sacrificial-material layer 432b′ and the third support material layer 432a′ are similar to the methods for forming the second sacrificial-material layer 431b′ and the second support material layer 431a′ in the above-described FIG. 5g and will not be described further.

In some implementations, the above-described etching the second insulating structure material layer 430′ to form the second through hole 482 may further include etching down the third support material layer 432a′, the third sacrificial-material layer 432b′, the second support material layer 431a′, and the second sacrificial-material layer 431b′ according to the mask pattern until the first electrode layer 451 and the contact structure 440 are exposed, as shown in FIG. 50.

The second electrode layer 452 may be formed by atomic layer deposition process or plasma vapor process. The first end of the second electrode layer 452 may be connected with the first electrode layer 451 and the contact structure 440, and the second end of the second electrode layer 452 is exposed from the surface of the third support material layer 432a′ away from the third sacrificial-material layer 432b′, as shown in FIG. 5p.

After forming the second electrode layer 452, a remaining portion of the part of the second through hole 482 constitutes the second sub-through hole in which an electrode contact material is filled to form an electrode contact layer 4820. The second electrode layer 452 may cover a sidewall and bottom of the electrode contact layer 4820. In some implementations, the second electrode layer 452 covers the sidewall of the electrode contact layer 4280. The material of the electrode contact layer 4820 includes polysilicon or doped polysilicon.

The third support material layer 432a′ is etched down according to the mask pattern to form the third opening 4321. The third opening 4321 exposes the third sacrificial-material layer 432b′ that can be removed via the third opening 4321 subsequently. Here, a remaining portion of the third support material layer 432a′ constitutes the third support layer 432, and the second insulating structure 430 includes the second support layer 431 and the third support layer 432, as shown in FIG. 5q.

The third sacrificial-material layer 432b′ is removed by wet etching to expose the second support material layer 431a′, thereby forming the third gap 4322 exposing the sidewall of the second electrode layer 452 between the third support layer 432 and the second support material layer 431a′, as shown in FIGS. 5P and 5q.

In FIGS. 5q to 5s, the methods for forming the first opening 4311, the first gap 4312, the second opening 4221, and the second gap 4231 are similar to the methods for forming the first opening 4311, the first gap 4312, the second opening 4221, and the second gap 4231 in FIGS. 5j to 5i and will not be further described.

In some implementations, the etch-selectivity ratio of the second sacrificial-material layer is greater than the etch-selectivity ratio of the third sacrificial-material layer. This facilitates adjusting the perpendicularity of the third gap and the first gap. The material of the third sacrificial-material layer includes silicon oxide. Implementations of the present disclosure are described with an example in which the third sacrificial-material layer includes boron-phosphorosilicate glass (BPSG) and the second sacrificial-material layer includes tetraethyl silicate (TEOS).

In some implementations, referring to FIGS. 5s and 5t, the above-described forming the second sub-capacitor dielectric layer 472 covering the exposed second electrode layer 452 further includes forming the second sub-capacitor dielectric layer 472 in the third gap 4322, and the above-described forming the second part 462 covering the second sub-capacitor dielectric layer 472 includes forming the second part 462 in the third gap 4322 formed with the second sub-capacitor dielectric layer 472.

A capacitor dielectric material is deposited in the third gap 4322 to form the second sub-capacitor dielectric layer 472, and a conductive material is deposited on the other side of the second sub-capacitor dielectric layer 472 to form the second part 462.

In some implementations, the second gap 4231, the first gap 4312, and the third gap 4322 are in communication with each other. The formed first sub-capacitor dielectric layer 471 and the second sub-capacitor dielectric layer 472 are connected; then, the first part covered on the first sub-capacitor dielectric layer 471 and the second part covered on the second sub-capacitor dielectric layer 472 are connected. In other implementations, the second gap 4231, the first gap 4312, and the third gap 4322 are not in communication with each other. The first sub-capacitor dielectric layer 471 in the second gap 4231 and the second sub-capacitor dielectric layer 472 in the first gap 4312 are separated by the first support layer 422; and the second sub-capacitor dielectric layer 472 in the first gap 4312 and the second sub-capacitor dielectric layer 472 in the third gap 4322 are separated by the second support layer 431.

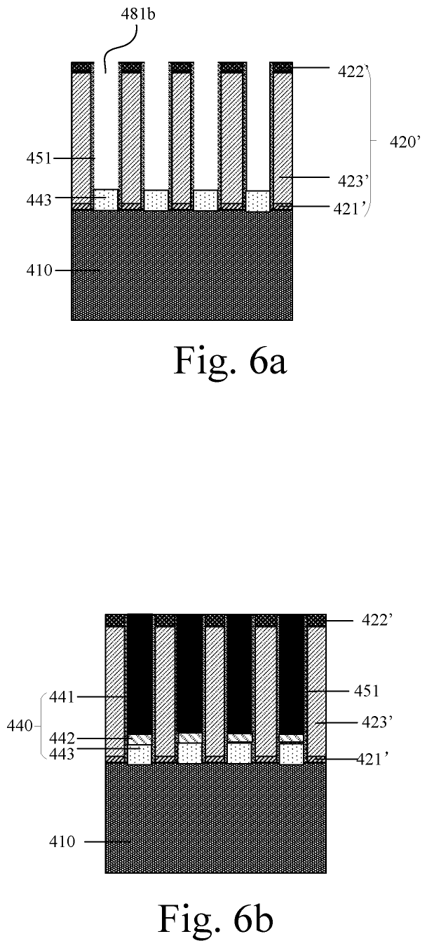

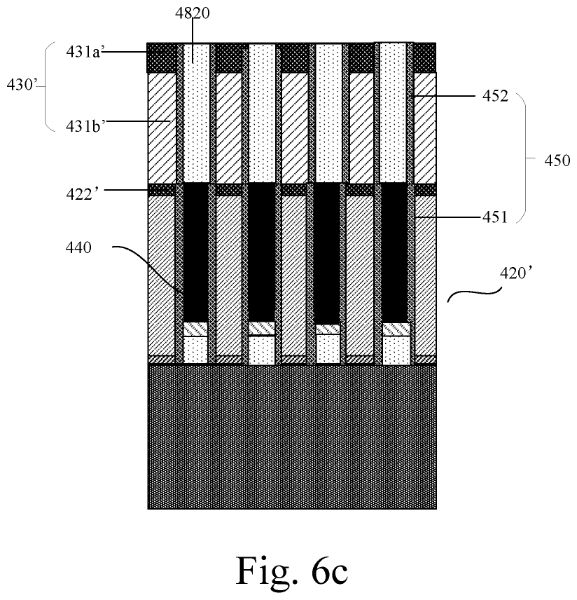

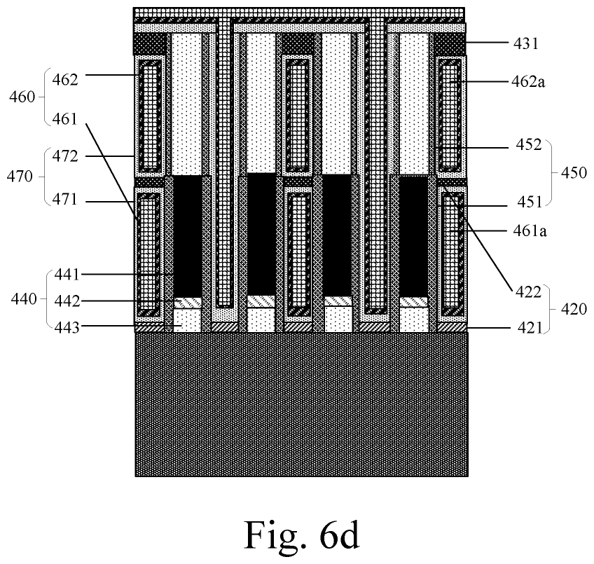

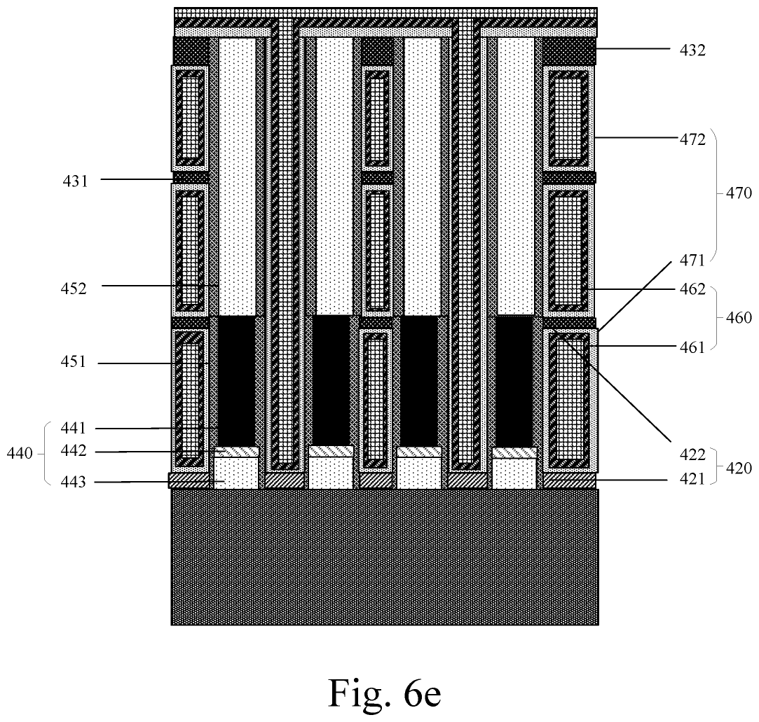

FIGS. 6a to 6e are diagram II of a fabrication process of a memory, according to an implementation of the present disclosure. The method of fabricating the memory provided by implementations of the present disclosure will be described in detail below in conjunction with FIGS. 5j to 5s and 6a to 6e.

Referring to FIG. 6a, the operation of providing the first semiconductor structure 410 may include providing a substrate. The operation of providing the first semiconductor structure 410 may include forming a semiconductor body over the substrate in the thickness direction of the first semiconductor structure 410. Here, the semiconductor body may be formed of the substrate (e.g., by etching or epitaxy). Here, the substrate not formed as semiconductor body may be removed in a subsequent process. Two ends of the semiconductor body are doped to form a source and a drain that may be doped with a P-type dopant (e.g., such as boron or gallium) or an N-type dopant (e.g., such as phosphorus and arsenic). A gate (not shown) is formed on at least one side of the semiconductor body. In the thickness direction of the first semiconductor structure 410, one or more channels (not shown) are formed between the source and the drain of the semiconductor body. A gate dielectric layer (not shown) is formed between the channel and the gate. The vertical transistor includes the gate and the semiconductor body. Shallow trench isolations (not shown) are formed between adjacent vertical transistors. Here, it may be possible to form shallow trench isolations between adjacent semiconductor bodies by photolithography process, etching process, and film deposition process.

In some implementations, the gate is formed on one side of the semiconductor body, then the vertical transistor is a single-gate transistor. In other implementations, gates are formed on at least two sides of the semiconductor body; then, the vertical transistor is a multi-gate transistor, which includes a gate-all-around transistor, a tri-gate transistor, or a dual-gate transistor. It is to be noted that the multi-gate transistor may have a large gate controlling area to realize a better channel control with a small sub-threshold swing.

The material of the substrate includes elementary semiconductor material such as silicon, germanium, III-V compound semiconductor, II-VI compound semiconductor material, organic semiconductors material, or other semiconductor material known in the art. The material of the shallow trench isolation includes at least one of silicon oxide, silicon nitride or silicon oxynitride.

In some implementations, still referring to FIG. 6a, the first insulating material layer 421′, the first sacrificial-material layer 423′, and the first support material layer 422′ covering the semiconductor structure 410 are formed in turn on the first semiconductor structure 410; and the first insulating material layer 421′, the first sacrificial-material layer 423′, and the first support material layer 422′ constitute the first insulating structure material layer 420′.

Here, the first insulating structure material layer 420′ is configured to form the first insulating structure 420 in a subsequent process. The first insulating material layer 421′ is configured to form the first insulating layer 421 in a subsequent process. The first support material layer 422′ is configured to form the first support layer 422 in a subsequent process. The first sacrificial-material layer 423′ will be removed in a subsequent process to form the second gap 4231. The material of the first sacrificial-material layer 423′ includes silicon oxide. Implementations of the present disclosure are described with an example in which the first sacrificial-material layer 423′ includes tetraethyl silicate (TEOS).

The material of the first insulating material layer 421′ may include insulating material such as at least one of silicon oxide, silicon nitride and silicon oxynitride, silicon boronitride, or silicon nitridecarbide. The material of the first support material layer 422′ may include at least one of carbon nitride, silicon nitride, or carbide, for example.

In some implementations, as shown in FIG. 6a, the first insulating material layer 421′ may include a single film and the present implementation will be described with an example in which the first insulating material layer 421′ includes silicon boronitride.

In some implementations, the first insulating structure material layer 420′ is etched to form a first through hole with bottom thereof exposing the semiconductor body (not shown). The first through hole 481 in FIG. 5b may be referred to as the first through hole.

In some implementations, referring to FIG. 6a, the above-described operation S405 includes forming the first electrode layer 451 covering the sidewall of the first through hole and forming the first sub-through hole 481b based on the topography of the first through hole. The bottom of the first sub-through hole 481b exposes the semiconductor body (not shown).

In some implementations, referring to FIGS. 6a and 6b, the above-described operation S403 may include forming the semiconductor layer 443 connected with the semiconductor body in the first sub-through hole 481b. The size of the semiconductor layer 443 is greater than the size of the first insulating material layer 421′ and smaller than the sum of the sizes of the first insulating material layer 421′ and the first sacrificial-material layer 423′ in the thickness direction of the first semiconductor structure 410. Operation S403 may also include forming the metal layer 441 connected with the semiconductor layer 443 on the semiconductor layer 443. The contact structure 440 may include the semiconductor layer 443 and the metal layer 441.

In some implementations, referring to FIG. 6a, the first electrode material layer (not shown) covering the sidewall and the bottom of the first through hole may be formed. The first electrode material layer at the bottom of the first through hole may be etched away. A remaining portion of the first electrode material layer may constitute the first electrode layer 451, and after forming the first electrode layer 451. The remaining portion of the part of the first through hole may constitute the first sub-through hole 481b.

In some implementations, referring to FIG. 6a, a semiconductor material layer (not shown) is deposited in the first sub-through hole 481b. The bottom of the semiconductor material layer is connected with the semiconductor body. The first electrode layer 451 covers the sidewall of the semiconductor material layer. In the thickness direction of the first semiconductor structure 410, the semiconductor material layer is etched to form the semiconductor layer 443. Here, in the thickness direction of the first semiconductor structure 410, the size of the semiconductor layer 443 is greater than the size of the first insulating material layer 421′ and smaller than the sum of the sizes of the first insulating material layer 421′ and the first sacrificial-material layer 423′. The material of the semiconductor material layer may include polysilicon or doped polysilicon, for example.

Referring to FIG. 6b, a metal conductive material is deposited on the semiconductor layer 443 to form the metal layer 441, and the first electrode layer 451 covers the sidewall of the metal layer 441. The first end of the metal layer 441 may be located in the first sacrificial-material layer 423′, and the second end of the metal layer 441 may be exposed from the surface of the first support material layer 422′ away from the first insulating material layer 421′. In some implementations, the orthographic projection of the formed metal layer 441 is a circle or an oval. In the thickness direction of the first semiconductor structure 410, the size of the metal layer 441 is greater than the size of the first support material layer 422′ and smaller than the sum of the sizes of the first support material layer 422′ and the first sacrificial-material layer 423′.

In some implementations, still referring to FIG. 6b, the above-described fabrication method may further include, before forming the metal layer 441, forming the connection layer 442 on the semiconductor layer 443. The sum of sizes of the connection layer 442 and the semiconductor layer 443 may be greater than the size of the first insulating material layer 421′ and smaller than the sum of the sizes of the first insulating material layer 421′ and the first sacrificial-material layer 423′ in the thickness direction of the first semiconductor structure 410. The material of the connection layer 442 may include a metal silicide, e.g., cobalt silicide, titanium silicide, or the like. The connection layer 442 is configured to reduce the contact resistance between the semiconductor layer 443 and the metal layer 441 and improve the electrical performance of the memory. In some implementations, the semiconductor layer 443, the connection layer 442 and the metal layer 441 constitute the contact structure 440; and the first electrode layer 451 covers the sidewall of the contact structure 440 and the bottom of the first electrode layer 451 is connected with the first semiconductor structure 410.

In some implementations, referring to FIG. 6c, forming the second insulating structure material layer 430′ covering the first insulating structure material layer 420′, the first electrode layer 451 and the contact structure 440 includes forming the second sacrificial-material layer 431b′ and the second support material layer 431a′ in turn on the first insulating structure material layer 420′. Here, the second insulating structure material layer 430′ is configured to form the second insulating structure 430 in a subsequent process. The second support material layer 431a′ is configured to form the second support layer 431 in a subsequent process. The second sacrificial-material layer 431b′ will be removed in a subsequent process to form the first gap 4312.

The material of the second support material layer 431a′ includes at least one of carbon nitride, nitride, or carbide. The materials of the second support material layer 431a′ and the first support material layer 422′ may be the same or different.

In some implementations, referring to FIG. 6c, the second insulating structure material layer 430′ is etched to form a second through hole penetrating through the second insulating structure material layer 430′, and the bottom of the second via exposes the first electrode layer 451 and the contact structure 440. The second through hole 482 in FIG. 5h may be referred to for the second through hole.

In some implementations, referring to FIG. 6c, after forming the second through hole, the second electrode material layer (not shown) covering the sidewall and bottom of the second via is formed in the second through hole, and the second electrode material layer covering the bottom of the second through hole is etched away, a remaining portion of the second electrode material layer may constitutes the second electrode layer 452 covering the sidewall of the second through hole.

Here, it may be possible to form the second electrode layer 452 by atomic layer deposition process or plasma vapor process. The first end of the second electrode layer 452 may be connected with the first electrode layer 451, and the second end of the second electrode layer 452 may be exposed from the surface of the second support material layer 431a′ away from the second sacrificial-material layer 431b′.

After forming the second electrode layer 452, a remaining portion of the part of the second through hole constitutes the second sub-through hole with the bottom thereof exposing the contact structure 440. An electrode contact material is filled in the second sub-through hole to form an electrode contact layer 4820 connected with the contact structure 440. The second electrode layer 452 may cover a sidewall of the electrode contact layer 4820. The material of the electrode contact layer 4820 includes polysilicon or doped polysilicon.

The material of the second electrode layer 452 include conductive materials such as at least one of semiconductor material (e.g., polysilicon, doped polysilicon etc.), metal (e.g., tungsten, titanium etc.), metal nitride (e.g., tungsten nitride, titanium nitride, tantalum nitride etc.) and metal silicide (e.g., titanium silicide, nickel silicide, titanium siliconitride etc.). The materials of the first electrode layer 451 and the second electrode layer 452 may be the same or different. Implementations of the present disclosure are described with an example in which the material of the second electrode layer 452 includes titanium nitride.

In some implementations, referring to FIGS. 5l and 6c, the memory includes the plurality of first electrode structures 450, the third through hole 483 penetrating through the second insulating structure material layer 430′, the first support material layer 422′ and the first sacrificial-material layer 423′ is formed. The third through hole 483 is located between adjacent two first electrode structures 450. The sidewall of the third through hole 483 exposes part of the first electrode layer 451 and part of the second electrode layer 452. The bottom of the third through hole 483 exposes the first insulating material layer 421′. Here, in the thickness direction of the first semiconductor structure 410, the first insulating structure material layer 420′ and the second insulating structure material layer 430′ are disposed in turn between adjacent two first electrode structures 450, and the third through hole 483 penetrating through the second insulating material layer 430′ includes penetrating through the second support material layer 431a′ and the second sacrificial-material layer 431b′.

A mask structure (not shown) covering the second support material layer 431a′ is formed. The mask structure may be a single film or a composite film. The mask structure may include one of silicon oxide, silicon nitride, silicon oxynitride, amorphous carbon, spin-coated carbon, or combinations thereof. It may be possible to form a mask pattern in the mask structure by self-aligning process and etch down the second support material layer 431a′ according to the mask pattern to form the first opening 4311. The first opening 4311 exposes the second sacrificial-material layer 431b′, which can be removed via the first opening 4311 subsequently. Here, a remaining portion of the second support material layer 431a′ constitutes the second support layer 431.

The second sacrificial-material layer 431b′ is removed by wet etching to expose the first support material layer 422′, thereby forming the first gap 4312 that exposes the sidewall of the second electrode layer 452 between the second support layer 431 and the first support material layer 422′ and has a bottom exposing the first support material layer 422′, as shown in FIG. 5j.

After removing the second sacrificial-material layer 431b′, the exposed first support material layer 422′ is continuously etched down according to the mask pattern to form the second opening 4221 exposing the first sacrificial-material layer 423′ that may be removed via the second opening 4221 subsequently. Here, a remaining portion of the first support material layer 422′ constitutes the first support layer 422, as shown in FIG. 5k.

The first sacrificial-material layer 423′ is removed by wet etching to expose the first insulating material layer 421′, thereby forming the second gap 4231 exposing the sidewall of the first electrode layer 451 between the first support layer 422 and the first insulating material layer 421′, and a remaining portion of the first insulating material layer 421′ constitutes the first insulating layer 421, as shown in FIG. 5l.

In some implementations, the etch-selectivity ratio of the second sacrificial-material layer is smaller than the etch-selectivity ratio of the first sacrificial-material layer. Here, the materials of the first sacrificial-material layer and the second sacrificial-material layer include silicon oxide. Implementations of the present disclosure are described with an example in which the first sacrificial-material layer and the second sacrificial-material layer include tetraethyl silicate (TEOS).

In some implementations, the concentrations of phosphorus element and boron element doped in the first sacrificial-material layer are greater than the concentrations of phosphorus element and boron element doped in the second sacrificial-material layer such that while etching the first sacrificial-material layer and the second sacrificial-material layer, the closer to the first semiconductor structure, the higher the etch rate is, which facilitates adjusting the perpendicularity of the sidewalls of the first gap and the second gap. In other implementations, the concentrations of phosphorus element and boron element doped in the first sacrificial-material layer are equal to the concentrations of phosphorus element and boron element doped in the second sacrificial-material layer such that while etching the first sacrificial-material layer and the second sacrificial-material layer, the etch rates are the same.

In some implementations, referring to FIGS. 5l and 6d, the capacitor dielectric layer 470 is formed. The capacitor dielectric layer 470 is located between the first electrode structure 450 and the second electrode structure 460. Forming the capacitor dielectric layer 470 includes depositing the capacitor dielectric material in the first gap 4312 to form the second sub-capacitor dielectric layer 472 and depositing the capacitor dielectric material in the second gap 4231 to form the first sub-capacitor dielectric layer 471. The first sub-capacitor dielectric layer 471 covers the exposed first electrode layer 451, and the second sub-capacitor dielectric layer covers the exposed second electrode layer 452. Here, the capacitor dielectric material includes at least one of low dielectric constant material (e.g., silicon oxide etc.) and high dielectric constant material (e.g., aluminum oxide etc.).

In some implementations, the first gap 4312 is in communication with the second gap 4231. Here, the formed first sub-capacitor dielectric layer 471 and second sub-capacitor dielectric layer 472 are connected. In some implementations, the first gap 4312 is not in communication with the second gap 4231. Here, the formed first sub-capacitor dielectric layer 471 and second sub-capacitor dielectric layer 472 are separated by the first support layer; and the first sub-capacitor dielectric layer 471 and the second sub-capacitor dielectric layer 472 may be formed in the same process and may also be formed one after another in different processes.

In some implementations, referring to FIG. 6d, the second electrode structure 460 is formed. The second electrode structure 460 includes the first part 461 in the first insulating structure 420 and the second part 462 in the second insulating structure 430, the first part 461 may cover a sidewall of part of the first electrode layer 451. The second part 462 may cover a sidewall of part of the second electrode layer 452.

In some implementations, still referring to FIG. 6d, a conductive material is deposited on the first sub-capacitor dielectric layer 471 and the second sub-capacitor dielectric layer 472 respectively to form the first part 461 and the second part 462. The conductive material includes at least one of semiconductor material (e.g., polysilicon, doped polysilicon etc.), metal (e.g., tungsten, titanium etc.), metal nitride (e.g., tungsten nitride, titanium nitride, tantalum nitride etc.), and metal silicide (e.g., titanium silicide, nickel silicide, titanium siliconitride etc.). Implementations of the present disclosure are described with an example in which the material of the second electrode structure 460 includes titanium nitride.

The first fill layer 461a is formed on a side of the first part 461 away from the first sub-capacitor dielectric layer 471, and the second fill layer 462a is formed on a side of the second part 462 away from the second sub-capacitor dielectric layer 472. The materials of the first fill layer 461a and the second fill layer 462a include polysilicon or silicon germanium. The materials of the first fill layer 461a and the second fill layer 462a may be the same or different.

In some implementations, the forming the second insulating structure material layer 430′ may further include, after forming the second support material layer 431a′, forming the third sacrificial-material layer 432b′ and the third support material layer 432a′ in turn on the second support material layer 431a′. The third sacrificial-material layer 432b′ may be located between the second support material layer 431a′ and the third support material layer 432a′.

In some implementations, the etching the second insulating structure material layer 430′ to form the second through hole 482 may further include etching down the third support material layer 432a′, the third sacrificial-material layer 432b′, the second support material layer 431a′, and the second sacrificial-material layer 431b′ according to the mask pattern until the first electrode layer 451 and the contact structure 440 are exposed, as shown in FIG. 50.

In some implementations, referring to FIGS. 5p and 6e, the second electrode material layer (not shown) covering the sidewall and bottom of the second through hole 482 may be formed by atomic layer deposition process or plasma vapor process. Here, the second electrode material layer covering the bottom of the second through hole 482 may be etched away, and a remaining portion of the second electrode material layer constitutes the second electrode layer 452 covering the sidewall of the second through hole 482. The first end of the second electrode layer 452 is connected with the first electrode layer 451, and the second end of the second electrode layer 452 is exposed from the surface of the third support material layer 432a′ away from the third sacrificial-material layer 432b′.

After forming the second electrode layer 452, a remaining portion of the part of the second through hole 482 that constitutes the second sub-through hole in which an electrode contact material may be filled to form the electrode contact layer 4820 covering the sidewall of the electrode contact layer 4820. The material of the electrode contact layer 4280 may include polysilicon or doped polysilicon, for example.

The third support material layer 432a′ is etched down according to the mask pattern to form the third opening 4321 exposing the third sacrificial-material layer 432b′ that can be removed via the third opening 4321 subsequently. Here, a remaining portion of the third support material layer 432a′ constitutes the third support layer 432, and the second insulating structure 430 includes the second support layer 431 and the third support layer 432, as shown in FIG. 5q.

The third sacrificial-material layer 432b′ may be removed by wet etching to expose the second support material layer 431a′, thereby forming the third gap 4322 exposing the sidewall of the second electrode layer 452 between the third support layer 432 and the second support material layer 431a′, as shown in FIG. 5q.

It is to be noted that in implementations of the present disclosure, referring to FIGS. 5q to 5s, the methods for forming the first opening 4311, the first gap 4312, the second opening 4221, and the second gap 4231 are similar to the methods for forming the first opening 4311, the first gap 4312, the second opening 4221 and the second gap 4231 as described above with reference to FIGS. 5j to 5i and will not be described further.

In some implementations, the etch-selectivity ratio of the second sacrificial-material layer may be greater than the etch-selectivity ratio of the third sacrificial-material layer. This facilitates adjusting the perpendicularity of the third gap and the first gap. The material of the third sacrificial-material layer may include silicon oxide, for example. Implementations of the present disclosure are described with an example in which the third sacrificial-material layer 432b′ includes boron-phosphorosilicate glass (BPSG) and the second sacrificial-material layer includes tetraethyl silicate (TEOS).

In some implementations, referring to FIGS. 5s and 6e, a capacitor dielectric material is deposited in the third gap 4322 to form the second sub-capacitor dielectric layer 472, and a conductive material is formed on the other side of the second sub-capacitor dielectric layer 472 to form the second part 462.

In some implementations, the second gap 4231, the first gap 4312 and the third gap 4322 are in communication with each other, the formed first sub-capacitor dielectric layer 471 and second sub-capacitor dielectric layer 472 may be connected; then, the first part covered on the first sub-capacitor dielectric layer 471 and the second part covered on the second sub-capacitor dielectric layer 472 are connected. In other implementations, the second gap 4231, the first gap 4312, and the third gap 4322 are not in communication with each other. The first sub-capacitor dielectric layer 471 in the second gap 4231 and the second sub-capacitor dielectric layer 472 in the first gap 4312 may be separated by the first support layer 422, and the second sub-capacitor dielectric layer 472 in the first gap 4312 and the second sub-capacitor dielectric layer 472 in the third gap 4322 may be separated by the second support layer 431.

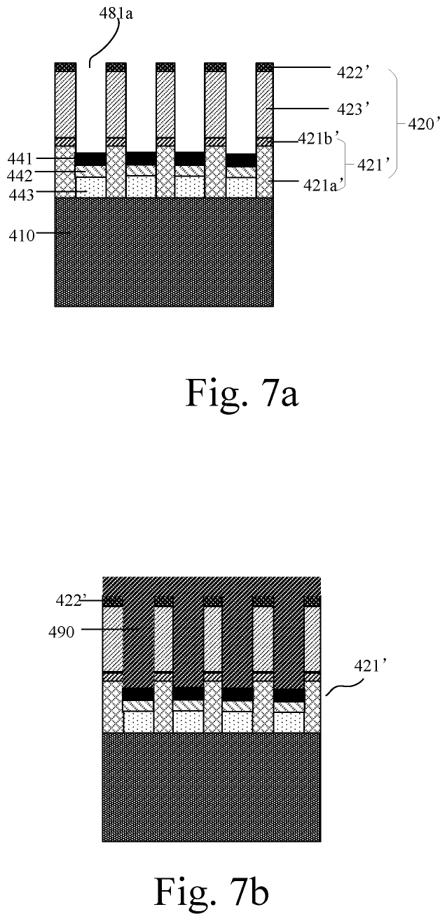

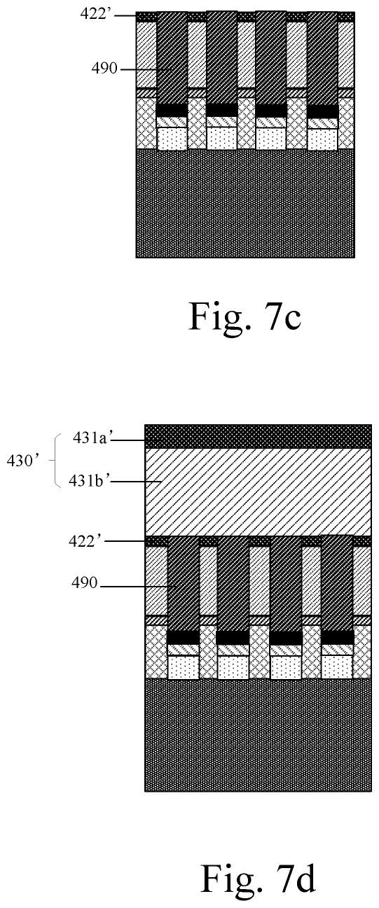

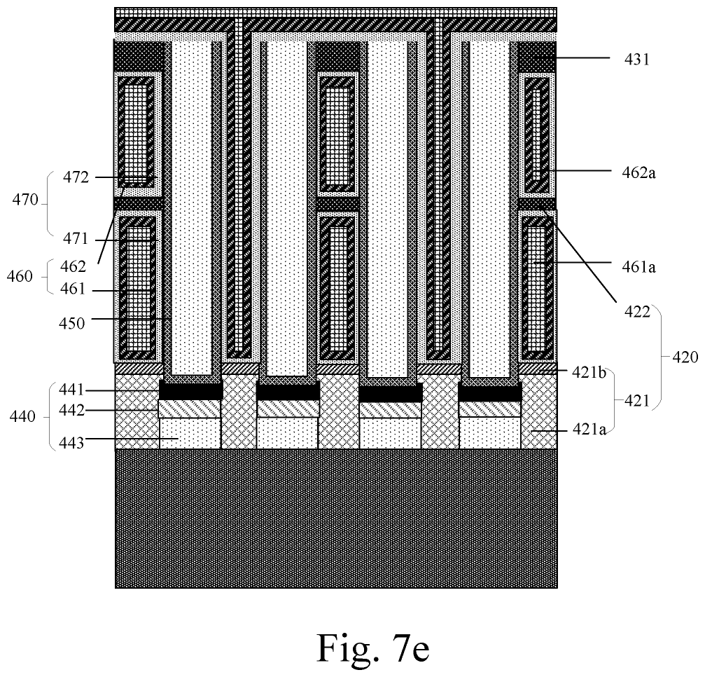

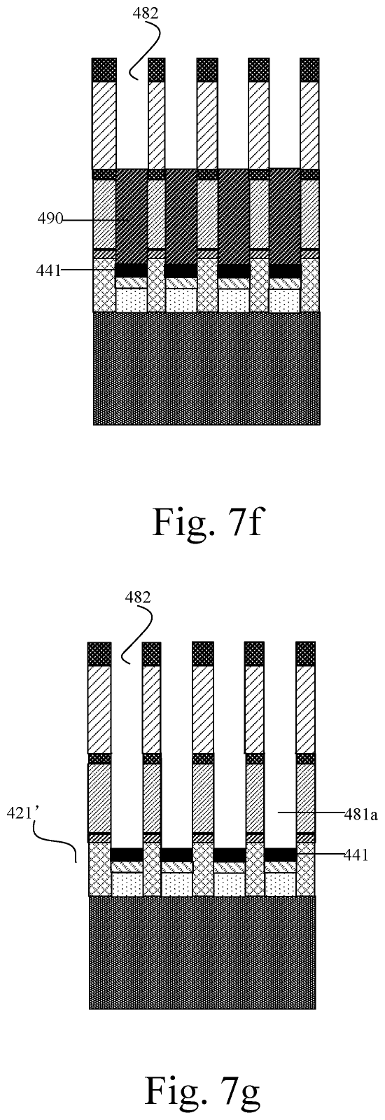

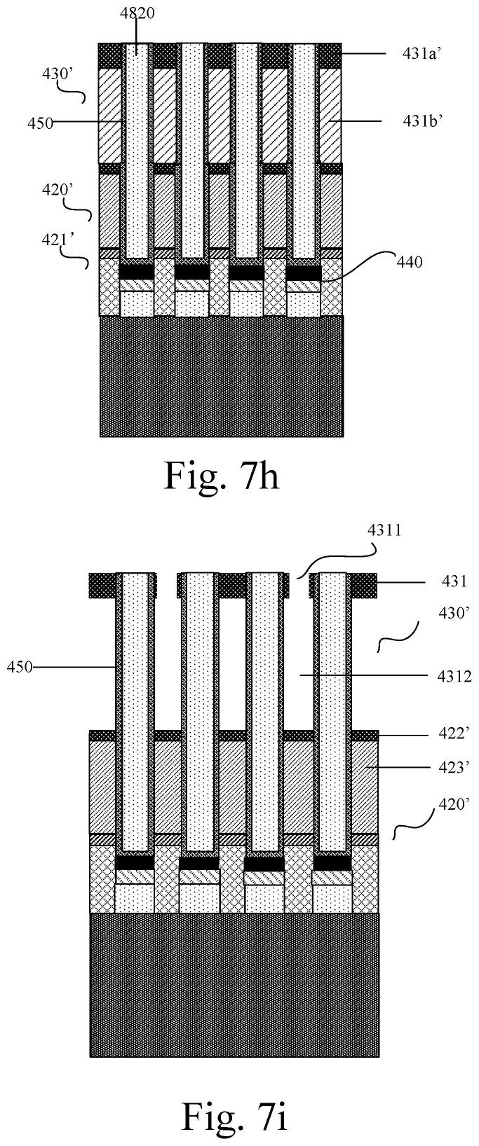

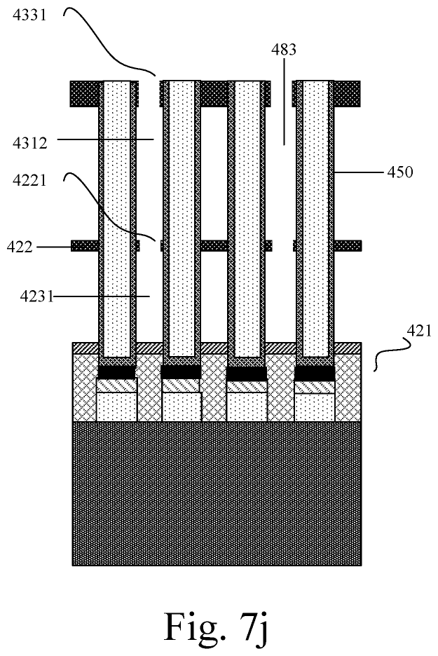

FIGS. 7a to 7j are diagram III of a fabrication process of a memory, according to an implementation of the present disclosure. The method of fabricating the memory provided by implementations of the present disclosure will be described in detail below according to FIGS. 7a to 7j.

Referring to FIG. 7a, the operation of providing the first semiconductor structure 410 may include providing a substrate. The providing the first semiconductor structure 410 may include forming a semiconductor body over the substrate in the thickness direction of the first semiconductor structure 410. Here, the semiconductor body may be formed of the substrate (e.g., by etching or epitaxy). Here, the substrate not formed as semiconductor body may be removed in a subsequent process. Two ends of the semiconductor body may be doped to form a source and a drain that may be doped with a P-type dopant (e.g., such as boron or gallium) or an N-type dopant (e.g., such as phosphorus and arsenic). A gate (not shown) is formed on at least one side of the semiconductor body. In the thickness direction of the first semiconductor structure 410, one or more channels (not shown) are formed between the source and the drain of the semiconductor body. A gate dielectric layer (not shown) is formed between the channel and the gate. The vertical transistor includes the gate and the semiconductor body. Shallow trench isolations (not shown) are formed between adjacent vertical transistors. Here, it may be possible to form shallow trench isolations between adjacent semiconductor bodies by photolithography process, etching process, and film deposition process.

In some implementations, the gate is formed on one side of the semiconductor body, then the vertical transistor is a single-gate transistor. In some implementations, gates are formed on at least two sides of the semiconductor body to provide a vertical transistor as a multi-gate transistor (e.g., a gate-all-around transistor, a tri-gate transistor, or a dual-gate transistor). It is to be noted that the multi-gate transistor may have a gate controlling area that is sized to improve channel control with a small sub-threshold swing.

The material of the substrate includes elementary semiconductor material such as silicon, germanium, III-V compound semiconductor, II-VI compound semiconductor material, organic semiconductors material, or other semiconductor material known in the art. The material of the shallow trench isolation includes at least one of silicon oxide, silicon nitride, or silicon oxynitride, for example.

In some implementations, referring to FIG. 7a, the first insulating material layer 421′, the first sacrificial-material layer 423′, and the first support material layer 422′ covering the semiconductor structure 410 are formed in turn on the first semiconductor structure 410, and the first insulating material layer 421′, the first sacrificial-material layer 423′ and the first support material layer 422′ may constitute the first insulating structure material layer 420′.

Here, the first insulating structure material layer 420′ is configured to form the first insulating structure 420 in a subsequent process, the first insulating material layer 421′ is configured to form the first insulating layer 421 in a subsequent process, the first support material layer 422′ is configured to form the first support layer 422 in a subsequent process, and the first sacrificial-material layer 423′ will be removed in a subsequent process to form the second gap 4231. The material of the first sacrificial-material layer 423′ includes silicon oxide. Implementations of the present disclosure are described with an example in which the first sacrificial-material layer 423′ includes tetraethyl silicate (TEOS).

The material of the first insulating material layer 421′ includes insulating material such as at least one of silicon oxide, silicon nitride and silicon oxynitride, silicon boronitride, silicon nitridecarbide. The material of the first support material layer 422′ includes at least one of carbon nitride, silicon nitride or carbide.

In some implementations, the first insulating material layer 421′ includes a composite film formed of a plurality of films.

In some implementations, the above-described forming the first insulating material layer 421′ covering the first semiconductor structure 410 includes forming the first sub-insulating material layer 421a′ and the second sub-insulating material layer 421b′ covering the first semiconductor structure 410 in turn. The first sacrificial-material layer 423′ may cover the second sub-insulating material layer 421b′. The present implementation will be described with an example in which the first sub-insulating material layer 421b′ includes silicon nitride and the second sub-insulating material layer 421b′ includes silicon boronitride.

In some implementations, referring to FIG. 7a, the first insulating structure material layer 420′ may be etched to form a first through hole. A bottom of the first through hole exposes the semiconductor body (not shown). The first through hole 481 in FIG. 5b may be referred to as the first through hole, in some implementations. A remaining portion of the first insulating material layer 421′ may constitute the first insulating layer 421, a remaining portion of the first sub-insulating material layer 421a′ may constitute the first sub-insulating layer 421a, and a remaining portion of the second sub-insulating material layer 421b′ may constitute the second sub-insulating layer 421b.

In some implementations, referring to FIG. 7a, a semiconductor material layer is deposited in the first through hole. The bottom of the semiconductor material layer is connected with the semiconductor body. In the thickness direction of the first semiconductor structure 410, the semiconductor material layer is etched until the size of the semiconductor material layer is smaller than the size of the first insulating material layer 421′. Here, a remaining portion of the semiconductor material layer may constitute the semiconductor layer 443. In some implementations, referring to FIG. 7a, in the thickness direction of the first semiconductor structure 410, the size of the semiconductor layer 443 is smaller than the size of the first sub-insulating material layer 421a′. Here, the material of the semiconductor material layer 443a may include polysilicon or doped polysilicon, for example.

In some implementations, still referring to FIG. 7a, after forming the semiconductor layer 443, the connection layer 442 is formed on the semiconductor layer 443. The sum of sizes of the connection layer 442 and the semiconductor layer 443 may be smaller than the size of the first insulating material layer 421′ in the thickness direction of the first semiconductor structure 410. The material of the connection layer 442 includes metal silicide such as cobalt silicide, titanium silicide, or the like. The connection layer 442 is configured to reduce the contact resistance between the semiconductor layer 443 and the metal layer 441 and improve the electrical performance of the memory.

After forming the semiconductor layer 443 and the connection layer 442, a remaining portion of the part of the first through hole constitutes the first sub-through hole 481a. Still referring to FIG. 7a, the metal layer 441 is deposited in the first sub-through hole 481a. In the thickness direction of the first semiconductor structure 410, the sum of the sizes of the metal layer 441, the connection layer 442 and the semiconductor layer 443 is smaller than the size of the first insulating material layer 421′.

Referring to FIG. 7b, after forming the metal layer 441, a first sub-sacrificial-material layer 490 is deposited in the first sub-through hole 481a. The first end of the first sub-sacrificial-material layer 490 contacts with the metal layer, and the second end of the first sub-sacrificial-material layer 490 covers the surface of the first support material layer 422′ away from the first insulating material layer 421′. The material of the first sub-sacrificial-material layer 490 includes carbon material such as spin-coated carbon, amorphous carbon, or the like. Here, it may be possible to planarize the first sub-sacrificial-material layer 490 until a surface of the first sub-sacrificial-material layer 490 is flush with a surface of the first support material layer 422′, as shown in FIG. 7c.

Referring to FIGS. 7d and 7e, forming the second insulating structure material layer 430′ on the first support material layer 422′ includes forming the second sacrificial-material layer 431b′ and the second support material layer 431a′ in turn on the first support material layer 422′ and forming a mask structure (not shown) covering the second support material layer 431a′. The mask structure may be a single film or a composite film. The mask structure may include one of silicon oxide, silicon nitride, silicon oxynitride, amorphous carbon, spin-coated carbon, or combinations thereof. It may be possible to form a mask pattern in the mask structure by self-aligning process and etch down the second insulating structure layer 430′ according to the mask pattern until the first sub-sacrificial-material layer 490 is exposed to form the second through hole 482. The first sub-sacrificial-material layer 490 is etched down along the second through hole 482 to expose the metal layer 441. The second through hole 482 is in communication with the first sub-through hole 481a. A bottom of the communicated second through hole 482 and first sub-through hole 481a may be located in the first insulating material layer 421′, as shown in FIG. 7f.

Referring to FIG. 7g, the first electrode structure 450 penetrating through the second insulating structure material layer 430′ and part of the first insulating structure material layer 420′ is formed on sidewalls and bottom of the communicated second through hole 482 and the first sub-through hole 481a by atomic layer deposition process or plasma vapor process. The first end of the first electrode structure 450 may be located in the first insulating structure material layer 421′, and the second end of the first electrode structure 450 may be exposed from the surface of the second support material layer 431a′ away from the second sacrificial-material layer 431b′. After forming the first electrode structure 450, a remaining portion of the parts of the communicated second through hole 482 and first sub-through hole 481a may constitute the second sub-through hole in which an electrode contact material is filled to form the electrode contact layer 4820. The material of the electrode contact layer 4820 may include polysilicon or doped polysilicon, for example.

In some implementations, referring to FIGS. 7g and 7h, a mask structure covering the second support material layer 431a′ is formed. The mask structure may be a single film or a composite film. The mask structure includes one of silicon oxide, silicon nitride, silicon oxynitride, amorphous carbon, spin-coated carbon, or combinations thereof. It may be possible to form a mask pattern in the mask structure by self-aligning process and etch down the second support material layer 431a′ according to the mask pattern to form the first opening 4311 exposing the second sacrificial-material layer 431b′ that can be removed via the first opening 4311 subsequently. Here, a remaining portion of the second support material layer 431a′ constitutes the second support layer 431.

The second sacrificial-material layer 431b′ is removed by wet etching to expose the first support material layer 422′, thereby forming the first gap 4312 exposing the sidewall of the first electrode structure 450 between the second support layer 431 and the first support material layer 422′, as shown in FIG. 7h.

In some implementations, referring to FIG. 7i, after removing the second sacrificial-material layer 431b′, the exposed first support material layer 422′ is continuously etched down according to the mask pattern to form the second opening 4221 exposing the first sacrificial-material layer 423′ that may be removed via the second opening 4221 subsequently. Here, a remaining portion of the first support material layer 422′ constitutes the first support layer 422.

The first sacrificial-material layer 423′ is removed by wet etching to expose the first insulating material layer 421′, thereby forming the second gap 4231 exposing the sidewall of the first electrode structure 450 between the first support layer 422 and the first insulating layer 421. Herein a remaining portion of the first insulating material layer 421′ may constitute the first insulating layer 421, as shown in FIG. 7i.

In some implementations, the etch-selectivity ratio of the second sacrificial-material layer is smaller than the etch-selectivity ratio of the first sacrificial-material layer. Here, the materials of the first sacrificial-material layer and the second sacrificial-material layer include silicon oxide. Implementations of the present disclosure are described with an example in which the first sacrificial-material layer and the second sacrificial-material layer include tetraethyl silicate (TEOS).

In some implementations, the concentrations of phosphorus element and boron element doped in the first sacrificial-material layer are greater than the concentrations of phosphorus element and boron element doped in the second sacrificial-material layer such that while etching the first sacrificial-material layer and the second sacrificial-material layer. The closer to the first semiconductor structure, the higher the etch rate is, which facilitates adjusting the perpendicularity of the sidewalls of the first gap and the second gap. In other implementations, the concentrations of phosphorus element and boron element doped in the first sacrificial-material layer are equal to the concentrations of phosphorus element and boron element doped in the second sacrificial-material layer such that while etching the first sacrificial-material layer and the second sacrificial-material layer, the etch rates are the same.

In some implementations, referring to FIG. 7j, the capacitor dielectric layer 470 is formed. The capacitor dielectric layer 470 may be located between the first electrode structure 450 and the second electrode structure 460. Forming the capacitor dielectric layer 470 may include depositing a capacitor dielectric material in the first gap 4312 to form the second sub-capacitor dielectric layer 472 and depositing a capacitor dielectric material in the second gap 4231 to form the first sub-capacitor dielectric layer 471. Here, the capacitor dielectric material may include at least one of low dielectric constant material (e.g., silicon oxide etc.) and high dielectric constant material (e.g., aluminum oxide etc.).

In some implementations, the first gap 4312 is in communication with the second gap 4231, the formed first sub-capacitor dielectric layer 471 and second sub-capacitor dielectric layer 472 are connected. In other implementations, the first gap 4312 is not in communication with the second gap 4231, the formed first sub-capacitor dielectric layer 471 and second sub-capacitor dielectric layer 472 are separated by the first support layer. Here, the first sub-capacitor dielectric layer 471 and the second sub-capacitor dielectric layer 472 may be formed in the same process and may also be formed one after another in different processes, which is not particularly limited in the present disclosure and may be selected by those skilled in the art according to practical demands.

In some implementations, referring to FIG. 7j, the second electrode structure 460 is formed. The second electrode structure 460 includes the first part 461 in the first insulating structure 420 and the second part 462 in the second insulating structure 430. The first part 461 may cover a sidewall of part of the first electrode structure 450 between the first support layer 422 and the first insulating layer 421, and the second part 462 may cover a sidewall of part of the first electrode structure 450 between the second support layer 431 and the first support layer 422.

In some implementations, still referring to FIG. 7j, a conductive material is deposited on the first sub-capacitor dielectric layer 471 and the second sub-capacitor dielectric layer 472 respectively to form the first part 461 and the second part 462. The conductive material includes at least one of semiconductor material (e.g., polysilicon, doped polysilicon etc.), metal (e.g., tungsten, titanium etc.), metal nitride (e.g., tungsten nitride, titanium nitride, tantalum nitride etc.), and metal silicide (e.g., titanium silicide, nickel silicide, titanium siliconitride etc.). Implementations of the present disclosure are described with an example in which the material of the second electrode structure 460 includes titanium nitride.

The first fill layer 461a is formed on a side of the first part 461 away from the first sub-capacitor dielectric layer 471, and the second fill layer 462a is formed on a side of the second part 462 away from the second sub-capacitor dielectric layer 472. The materials of the first fill layer 461a and the second fill layer 462a may include polysilicon or silicon germanium, for example. The materials of the first fill layer 461a and the second fill layer 462a may be the same or different, which is not particularly limited in the present disclosure.

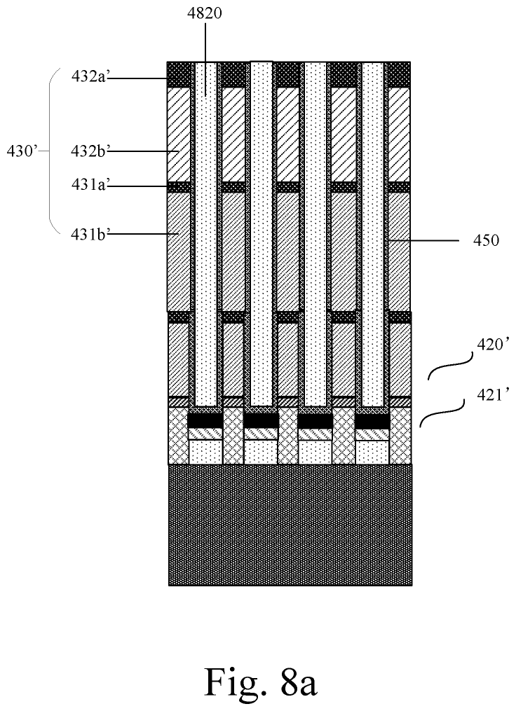

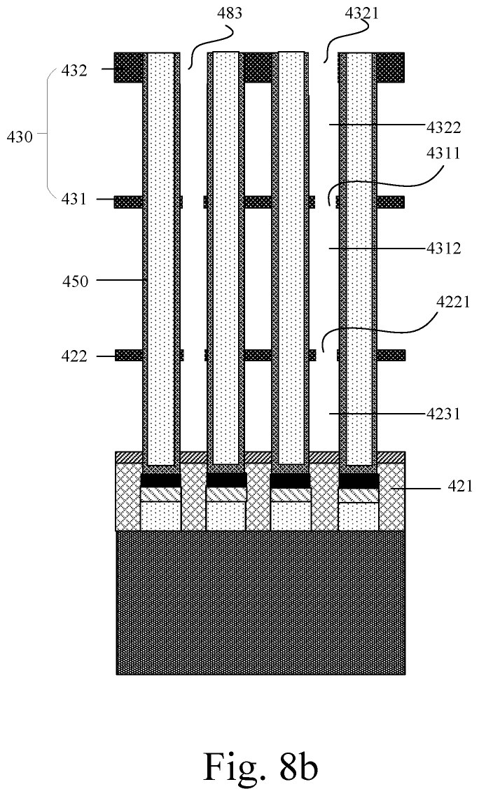

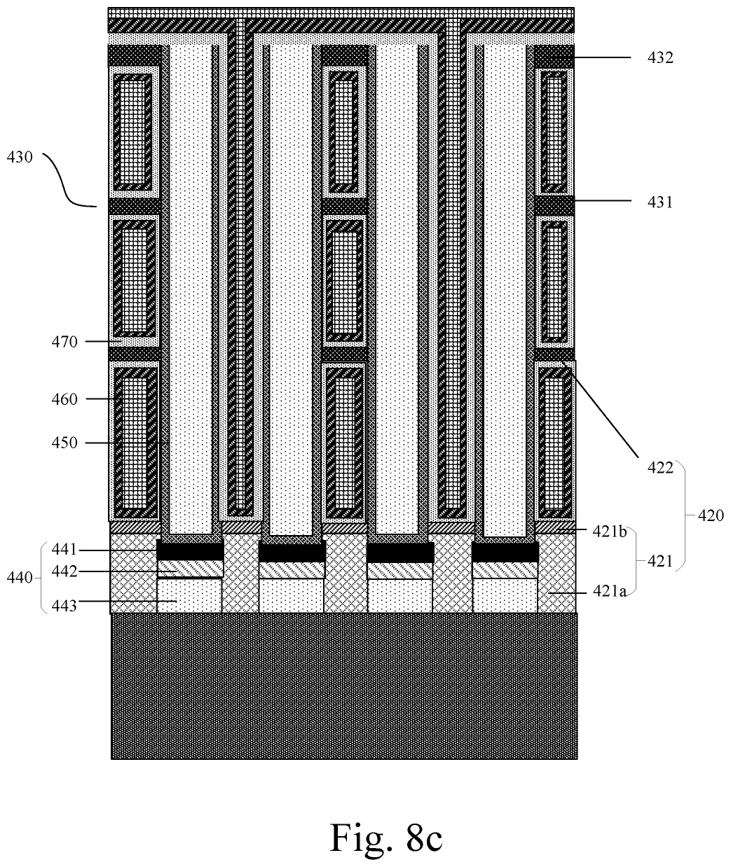

FIGS. 8a to 8c are diagram IV of a fabrication process of a memory, according to an implementation of the present disclosure. The method of fabricating the memory provided by implementations of the present disclosure will be described in detail below in conjunction with FIGS. 7a to 7c and 8a to 8d.

Referring to FIG. 7a, the operation of providing the first semiconductor structure 410 may include providing a substrate. The providing the first semiconductor structure 410 may include forming a semiconductor body over the substrate in the thickness direction of the first semiconductor structure 410. Here, the semiconductor body may be formed of the substrate (e.g., by etching or epitaxy). Here, the substrate not formed as semiconductor body may be removed in a subsequent process. Two ends of the semiconductor body may be doped to form a source and a drain that may be doped with a P-type dopant (e.g., such as boron or gallium) or an N-type dopant (e.g., such as phosphorus and arsenic). A gate (not shown) is formed on at least one side of the semiconductor body. In the thickness direction of the first semiconductor structure 410, one or more channels (not shown) are formed between the source and the drain of the semiconductor body. A gate dielectric layer (not shown) is formed between the channel and the gate. The vertical transistor includes the gate and the semiconductor body. Shallow trench isolations (not shown) are formed between adjacent vertical transistors. Here, it may be possible to form shallow trench isolations between adjacent semiconductor bodies by photolithography process, etching process and film deposition process.

In some implementations, the gate may be formed on one side of the semiconductor body. Here, the vertical transistor may be a single-gate transistor. In some implementations, gates may be formed on at least two sides of the semiconductor body; here, the vertical transistor may be a multi-gate transistor (e.g., a gate-all-around transistor, a tri-gate transistor, or a dual-gate transistor). It is to be noted that the multi-gate transistor may have a large gate controlling area to realize a better channel control with a small sub-threshold swing.

The material of the substrate includes elementary semiconductor material such as silicon, germanium, III-V compound semiconductor, II-VI compound semiconductor material, organic semiconductors material or other semiconductor material known in the art. The material of the shallow trench isolation includes at least one of silicon oxide, silicon nitride or silicon oxynitride.

In some implementations, referring to FIG. 7a, the first insulating material layer 421′, the first sacrificial-material layer 423′, and the first support material layer 422′ covering the semiconductor structure 410 are formed in turn on the first semiconductor structure 410, and the first insulating material layer 421′, the first sacrificial-material layer 423′, and the first support material layer 422′ constitute the first insulating structure material layer 420′.

Here, the first insulating structure material layer 420′ is configured to form the first insulating structure 420 in a subsequent process, the first insulating material layer 421′ is configured to form the first insulating layer 421 in a subsequent process, the first support material layer 422′ is configured to form the first support layer 422 in a subsequent process, and the first sacrificial-material layer 423′ will be removed in a subsequent process to form the second gap 4231. The material of the first sacrificial-material layer 423′ includes silicon oxide. Implementations of the present disclosure are described with an example in which the first sacrificial-material layer 423′ includes tetraethyl silicate (TEOS).

The material of the first insulating material layer 421′ may include an insulating material such as at least one of silicon oxide, silicon nitride, silicon oxynitride, silicon boronitride, silicon nitridecarbide, etc., The material of the first support material layer 422′ includes at least one of carbon nitride, silicon nitride, or carbide, for example.

In some implementations, the first insulating material layer 421′ includes a composite film formed of a plurality of films. In other implementations, the first insulating material layer 421′ may include a single film, by way of example and not limitation.

In some implementations, the above-described forming the first insulating material layer 421′ covering the first semiconductor structure 410 may include forming the first sub-insulating material layer 421a′ and the second sub-insulating material layer 421b′ covering the first semiconductor structure 410 in turn. The first sacrificial-material layer 423′ covers the second sub-insulating material layer 421b′.

In some implementations, referring to FIG. 7a, the first insulating structure material layer 420′ is etched to form a first through hole. A bottom of the first through hole exposes the semiconductor body (not shown), as shown by the first through hole 481 in FIG. 5b. A remaining portion of the first insulating material layer 421′ constitutes the first insulating layer 421, a remaining portion of the first sub-insulating material layer 421a′ constitutes the first sub-insulating layer 421a, and a remaining portion of the second sub-insulating material layer 421b′ constitutes the second sub-insulating layer 421b.

In some implementations, referring to FIG. 7a, a semiconductor material layer may be deposited in the first through hole 481. A bottom of the semiconductor material layer may be connected with the semiconductor body. In the thickness direction of the first semiconductor structure 410, the semiconductor material layer may be etched until the size of the semiconductor material layer is smaller than the size of the first insulating material layer 421′; here, a remaining portion of the semiconductor material layer may constitute the semiconductor layer 443. In some implementations, referring to FIG. 7a, in the thickness direction of the first semiconductor structure 410, the size of the semiconductor layer 443 is smaller than the size of the first sub-insulating material layer 421a′. Here, the material of the semiconductor material layer 443a includes polysilicon or doped polysilicon.

In some implementations, still referring to FIG. 7a, after forming the semiconductor layer 443, the connection layer 442 is formed on the semiconductor layer 443. The sum of sizes of the connection layer 442 and the semiconductor layer 443 may be smaller than the size of the first insulating material layer 421′ in the thickness direction of the first semiconductor structure 410. The material of the connection layer 442 may include metal silicide such as cobalt silicide, titanium silicide, or the like. The connection layer 442 may be configured to reduce the contact resistance between the semiconductor layer 443 and the metal layer 441 and improve the electrical performance of the memory.

After forming the semiconductor layer 443 and the connection layer 442, a remaining portion of the part of the first through hole 481 constitutes the first sub-through hole 481a. Still referring to FIG. 7a, the metal layer 441 is deposited in the first sub-through hole 481a. In the thickness direction of the first semiconductor structure 410, the sum of the sizes of the metal layer 441, the connection layer 442 and the semiconductor layer 442 is smaller than the size of the first insulating material layer 421′.

Referring to FIG. 7b, after forming the metal layer 441, the first sub-sacrificial-material layer 490 is deposited in the first sub-through hole 481a. The first end of the first sub-sacrificial-material layer 490 contacts with the metal layer, and the second end of the first sub-sacrificial-material layer 490 covers the surface of the first support material layer 422′ away from the first insulating material layer 421′. The material of the first sub-sacrificial-material layer 490 includes carbon material such as spin-coated carbon or amorphous carbon etc. Here, it is also possible to planarize the first sub-sacrificial-material layer 490 until a surface of the first sub-sacrificial-material layer 490 is flush with a surface of the first support material layer 422′, as shown in FIG. 7c.

Referring to FIG. 8a, forming the second insulating structure material layer 430′ on the first support material layer 422′ includes forming the first insulating structure material layer 431b′, the second support material layer 431a′, the third sacrificial-material layer 432b′, and the third support material layer 432a′ in turn on the first support material layer. Providing the third sacrificial-material layer 432b′ and the third support material layer 432a′ facilitates further increasing the effective height of the first electrode structure 450, thereby further increasing the effective direct-facing area between the first electrode structure 450 and the second electrode structure 460, and increasing the capacitance value of the capacitor.

In some implementations, referring to FIGS. 7f and 8a, a mask structure (not shown) covering the third support material layer 432a′ is formed. The mask structure may be a single film or a composite film. The mask structure includes one of silicon oxide, silicon nitride, silicon oxynitride, amorphous carbon, spin-coated carbon, or combinations thereof. It may be possible to form a mask pattern in the mask structure by self-aligning process and etch down the second insulating structure layer 430′ according to the mask pattern until the first sub-sacrificial-material layer 490 is exposed to form the second through hole 482. The first sub-sacrificial-material layer 490 is etched down along the second through hole 482 to expose the metal layer 441. The second through hole 482 is in communication with the first sub-through hole 481a. A bottom of the communicated second through hole 482 and first sub-through hole 481a may be located in the first insulating material layer 421′.

Referring to FIG. 8a, the first electrode structure 450 penetrating through the second insulating structure material layer 430′ and part of the first insulating structure material layer 420′ is formed on the sidewalls and bottom of the communicated second through hole 482 and the first sub-through hole 481a by atomic layer deposition process or plasma vapor process. The first end of the first electrode structure 450 is located in the first insulating structure material layer 421′, and the second end of the first electrode structure 450 is exposed from the surface of the third support material layer 432a′ away from the third sacrificial-material layer 432b′. After forming the first electrode structure 450, a remaining portion of the parts of the communicated second through hole 482 and first sub-through hole 481a constitute the second sub-through hole in which an electrode contact material is filled to form the electrode contact layer 4820. The material of the electrode contact layer 4820 includes polysilicon or doped polysilicon.

In some implementations, referring to FIGS. 8a and 8b, a mask structure covering the third support material layer 432a′ is formed. The mask structure may be a single film or a composite film. The mask structure may include one of silicon oxide, silicon nitride, silicon oxynitride, amorphous carbon, spin-coated carbon, or combinations thereof. It may be possible to form a mask pattern in the mask structure by self-aligning process and etch down the third support material layer 432a′ according to the mask pattern to form the third opening 4321 exposing the third sacrificial-material layer 432b′ that can be removed via the third opening 4321 subsequently. Here, a remaining portion of the third support material layer 432a′ constitutes the third support layer 432, and the second insulating structure 430 includes the second support layer 431 and the third support layer 432.

The third sacrificial-material layer 432b′ may be removed by wet etching to expose the second support material layer 431a′, thereby forming the third gap 4322 exposing the sidewall of the first electrode structure 450 between the third support layer 432 and the second support material layer 431a′.

In some implementations, still referring to FIGS. 8a and 8b, the second support material layer 431a′ is etched down according to the mask pattern to form the first opening 4311 exposing the second sacrificial-material layer 431b′ that can be subsequently removed via the first opening 4311. Here, a remaining portion of the second support material layer 431a′ constitutes the second support layer 431.

The second sacrificial-material layer 431b′ is removed by wet etching to expose the first support material layer 422′, thereby forming the first gap 4312 exposing the sidewall of the first electrode structure 450 between the second support layer 431 and the first support material layer 422′,

In some implementations, still referring to FIGS. 8a and 8b, after removing the second sacrificial-material layer 431b′, the exposed first support material layer 422′ is continuously etched down according to the mask pattern to form the second opening 4221 exposing the first sacrificial-material layer 423′ that can be removed via the second opening 4221 subsequently. Here, a remaining portion of the first support material layer 422′ constitutes the first support layer 422.

The first sacrificial-material layer 423′ is removed by wet etching to expose the first insulating material layer 421′, thereby forming the second gap 4231 exposing the sidewall of the first electrode structure 450 between the first support layer 422 and the first insulating layer 421, and a remaining portion of the first insulating material layer 421′ constitutes the first insulating layer 421, as shown in FIG. 8b.

In some implementations, the etch-selectivity ratio of the second sacrificial-material layer is smaller than the etch-selectivity ratio of the first sacrificial-material layer. Here, the materials of the first sacrificial-material layer and the second sacrificial-material layer include silicon oxide. Implementations of the present disclosure are described with an example in which the first sacrificial-material layer and the second sacrificial-material layer include tetraethyl silicate (TEOS).

In some implementations, the concentrations of phosphorus element and boron element doped in the first sacrificial-material layer are greater than the concentrations of phosphorus element and boron element doped in the second sacrificial-material layer such that while etching the first sacrificial-material layer and the second sacrificial-material layer, the closer to the first semiconductor structure, the higher the etch rate is. This adjusts the perpendicularity of the sidewalls of the first gap and the second gap. In other implementations, the concentrations of phosphorus element and boron element doped in the first sacrificial-material layer are equal to the concentrations of the phosphorus element and boron element doped in the second sacrificial-material layer such that while etching the first sacrificial-material layer and the second sacrificial-material layer, the etch rates are the same.

In some implementations, referring to FIG. 8c, the capacitor dielectric layer 470 is formed. The capacitor dielectric layer 470 is located between the first electrode structure 450 and the second electrode structure 460. Forming the capacitor dielectric layer 470 includes depositing a capacitor dielectric material in the first gap 4312 to form the second sub-capacitor dielectric layer 472 and depositing a capacitor dielectric material in the second gap 4231 to form the first sub-capacitor dielectric layer 471. Here, the capacitor dielectric material includes at least one of low dielectric constant material (e.g., silicon oxide, etc.) and high dielectric constant material (e.g., aluminum oxide, etc.).

In some implementations, the first gap 4312 is in communication with the second gap 4231, the formed first sub-capacitor dielectric layer 471 and second sub-capacitor dielectric layer 472 are connected. In other implementations, the first gap 4312 is not in communication with the second gap 4231, the formed first sub-capacitor dielectric layer 471 and second sub-capacitor dielectric layer 472 are separated by the first support layer. Here, the first sub-capacitor dielectric layer 471 and the second sub-capacitor dielectric layer 472 may be formed in the same process and may also be formed one after another in different processes, which is not particularly limited in the present disclosure and may be selected by those skilled in the art according to practical demands.

In some implementations, referring to FIG. 8c, the second electrode structure 460 is formed. The second electrode structure 460 includes the first part 461 in the first insulating structure 420 and the second part 462 in the second insulating structure 430, the first part 461 may cover a sidewall of part of the first electrode structure 450 between the first support layer 422 and the first insulating layer 421, and the second part 462 may cover a sidewall of part of the first electrode structure 450 between the second support layer 431 and the first support layer 422.

In some implementations, still referring to FIG. 8c, a conductive material is deposited on the first sub-capacitor dielectric layer 471 and the second sub-capacitor dielectric layer 472 respectively to form the first part 461 and the second part 462. The conductive material includes at least one of semiconductor material (e.g., polysilicon, doped polysilicon, etc.), metal (e.g., tungsten, titanium, etc.), metal nitride (e.g., tungsten nitride, titanium nitride, tantalum nitride, etc.) and metal silicide (e.g., titanium silicide, nickel silicide, titanium siliconitride, etc.). Implementations of the present disclosure are described with an example in which the material of the second electrode structure 460 includes titanium nitride.

The first fill layer 461a is formed on a side of the first part 461 away from the first sub-capacitor dielectric layer 471 and the second fill layer 462a is formed on a side of the second part 462 away from the second sub-capacitor dielectric layer 472. The materials of the first fill layer 461a and the second fill layer 462a include polysilicon or silicon germanium. The materials of the first fill layer 461a and the second fill layer 462a may be the same or different, which is not particularly limited in the present disclosure.

Based on the above-described memory, the present disclosure further provides a memory system including one or more memories as described in any one of the above-described implementations. The memory system may include a memory controller coupled to the memories and configured to control the memories.

The memory system includes a mobile phone, a laptop computer, a tablet, a vehicle computer, a gaming console, a printer, a positioning device, a wearable electronic device, a smart sensor, a virtual reality (VR) device, an argument reality (AR) device, or any other suitable electronic devices having memory therein.

In some implementations, the memory controller is designed for operating in a low duty-cycle environment like secure digital (SD) cards, compact flash (CF) cards, universal serial bus (USB) flash drives, or other media for use in electronic devices, such as personal computers, digital cameras, mobile phones, etc.

In some implementations, the memory controller is designed for operating in a high duty-cycle environment, such as solid-state drives (SSDs) or embedded multi-media cards (eMMCs) used as data memory for mobile devices, such as smartphones, tablets, laptop computers, etc., and enterprise storage arrays.

The memory controller may be configured to control operations of the memory, such as read, erase, and program operations. The memory controller may be further configured to manage various functions with respect to data stored or to be stored in the memory including, but not limited to bad-block management, garbage collection, logical-to-physical address conversion, wear leveling, etc. In some implementations, the memory controller is further configured to process error correction codes with respect to the data read from or written to the memory.

The memory controller may further perform any other suitable functions as well, for example, formatting the memory. The memory controller may communicate with an external device (e.g., a host) according to a particular communication protocol. For example, the memory controller may communicate with the external device through at least one of various interface protocols, such as a USB protocol, an MMC protocol, a peripheral component interconnection protocol, a PCI-express protocol, an advanced technology attachment protocol, a serial protocol, a parallel protocol, a small computer small interface protocol, an enhanced small disk interface protocol, an integrated drive electronics protocol, a Firewire protocol, etc.

The memory controller and one or more memory can be integrated into various types of storage devices, for example, be included in the same package, such as a universal flash storage (UFS) package or an eMMC package.

Based on the above-described memory system, implementations of present disclosure further provide an electronic device including the memory system as described in the above implementation. The electronic device may include a host coupled to the memory system.

The electronic device comprises a mobile phone, a desktop computer, a tablet, a notebook, a server, a vehicle device, a wearable device, a mobile power supply, etc.

The host may be a processor of an electronic device, such as a central processing unit (CPU), or a system-on-chip (SOC), such as an application processor (AP). The host may be configured to send data to the memory. Alternatively, the host may be configured to receive data from the memory.

The above descriptions are merely specific implementations of the present disclosure, but the protection scope of the present disclosure is not limited thereto. Any variation or replacement that may be readily figured out by those skilled in the art within the technical scope disclosed by the present disclosure shall fall within the protection scope of the present disclosure. Therefore, the protection scope of the present disclosure shall be defined by the protection scope of the claims.

What is claimed is:

1. A memory, comprising:
a first semiconductor structure comprising a vertical transistor;
a first insulating structure and a second insulating structure stacked in turn on the first semiconductor structure;
a contact structure penetrating through the first insulating structure and connected with a semiconductor body of the vertical transistor;
a first electrode structure comprising a first electrode layer penetrating through at least part of the first insulating structure and a second electrode layer penetrating through the second insulating structure, the first electrode layer covering a sidewall of at least part of the contact structure and being connected with the contact structure, and the second electrode layer being connected with the first electrode layer;
a second electrode structure comprising a first part in the first insulating structure and a second part in the second insulating structure, the first part covering a sidewall of part of the first electrode layer, and the second part covering a sidewall of part of the second electrode layer; and
a capacitor dielectric layer between the first electrode structure and the second electrode structure.

2. The memory of claim 1, wherein:
the first insulating structure comprises a first insulating layer and a first support layer stacked in turn on the first semiconductor structure,
the first insulating layer is disposed as being spaced apart from the first support layer, and
the first part is located between the first insulating layer and the first support layer.

3. The memory of claim 2, wherein:
the contact structure comprises a metal layer and a semiconductor layer,
the metal layer penetrates through the first support layer and extends into the first insulating layer,
the semiconductor layer is located between the semiconductor layer and the metal layer, and
the first electrode layer comprises a first sub-electrode layer over the semiconductor layer and covering sidewall of the metal layer.

4. The memory of claim 3, wherein the first electrode layer further comprises a second sub-electrode layer between the semiconductor layer and the metal layer.

5. The memory of claim 2, wherein:
the contact structure comprises a metal layer and a semiconductor layer,
the metal layer penetrates through the first support layer and extends to between the first insulating layer and the first support layer,
the semiconductor layer is located between the semiconductor layer and the metal layer, and
the first electrode layer is located over the first semiconductor structure and may cover a sidewalls of the semiconductor layer and the metal layer.

6. The memory of claim 3, wherein the contact structure comprises a connection layer between the semiconductor layer and the metal layer.

7. The memory of claim 1, wherein:
the second insulating structure comprises a second support layer,
the second support layer is disposed as being spaced apart from the first insulating structure, and
the second part is located between the first insulating structure and the second support layer.

8. The memory of claim 7, wherein:
the second insulating structure further comprises a third support layer,
the third support layer is disposed as being spaced apart from the second support layer, and
the second part is further located between the second support layer and the third support layer.

9. A method of fabricating a memory, comprising:
providing a first semiconductor structure, the first semiconductor structure comprising a vertical transistor;
forming a first insulating structure covering the first semiconductor structure;
forming a contact structure penetrating through the first insulating structure, the contact structure being connected with a semiconductor body of the vertical transistor;
forming a second insulating structure covering the contact structure and the first insulating structure;
forming a first electrode structure, the first electrode structure comprising a first electrode layer penetrating through at least part of the first insulating structure and a second electrode layer penetrating through the second insulating structure, the first electrode layer covering sidewall of at least part of the contact structure and is connected with the contact structure, and the second electrode layer being connected with the first electrode layer;
forming a second electrode structure, the second electrode structure comprising a first part in the first insulating structure and a second part in the second insulating structure, the first part covering sidewall of part of the first electrode layer, and the second part covering sidewall of part of the second electrode layer; and
forming a capacitor dielectric layer, the capacitor dielectric layer being located between the first electrode structure and the second electrode structure.

10. The method of claim 9, further comprising:
forming a first insulating structure material layer covering the first semiconductor structure, the first insulating structure material layer comprising a first insulating material layer, a first sacrificial-material layer, and a first support material layer stacked in turn; and
forming a first through hole penetrating through the first insulating structure material layer, a bottom of the first through hole exposing the semiconductor body,
wherein the forming the contact structure penetrating through the first insulating structure comprises:
forming a semiconductor layer in the first through hole and connected with the semiconductor body, a size of the semiconductor layer being smaller than a size of the first insulating material layer in a thickness direction of the first semiconductor structure; and
forming a metal layer on the semiconductor layer and connected with the semiconductor layer, the contact structure comprising the semiconductor layer and the metal layer;
wherein the forming the first electrode structure comprises:
after forming the semiconductor layer, forming a first sub-through hole based on a topography of the first through hole, a bottom of the first sub-through hole exposing the semiconductor layer; and
forming the first electrode layer covering sidewall and bottom of the first sub-through hole, and
wherein the forming the metal layer on the semiconductor layer comprises:
forming the metal layer in the first sub-through hole formed with the first electrode layer.

11. The method of claim 9, further comprising:
forming a first insulating structure material layer covering the first semiconductor structure, the first insulating structure material layer comprising a first insulating material layer, a first sacrificial-material layer, and a first support material layer stacked in turn;
forming a first through hole penetrating through the first insulating structure material layer, a bottom of the first through hole exposing the semiconductor body,
wherein the forming the first electrode structure comprising:
forming the first electrode layer covering sidewall of the first through hole; and
forming a first sub-through hole based on a topography of the first through hole, a bottom of the first sub-through hole exposing the semiconductor body,
wherein the forming the contact structure penetrating through the first insulating structure comprises:
forming a semiconductor layer in the first sub-through hole and connected with the semiconductor body, a size of the semiconductor layer being greater than a size of the first insulating material layer and smaller than a sum of sizes of the first insulating material layer and the first sacrificial-material layer in a thickness direction of the first semiconductor structure; and
forming a metal layer on the semiconductor layer and connected with the semiconductor layer, the contact structure comprising the semiconductor layer and the metal layer.

12. The method of claim 10, further comprising:
forming a second insulating structure material layer covering the first insulating structure material layer, the first electrode layer, and the contact structure, the second insulating structure material layer comprising a second sacrificial-material layer and a second support material layer stacked in turn; and
forming a second through hole penetrating through the second insulating structure material layer, a bottom of the second through hole exposing the first electrode layer and the contact structure,
wherein the forming the first electrode structure further comprises:
forming the second electrode layer at least covering sidewall of the second through hole; and
forming a second sub-through hole based on a topography of the second through hole, and
wherein the method further comprises:
filling the second sub-through hole to form an electrode contact layer.

13. The method of claim 12, wherein:
the memory comprises a plurality of the first electrode structures, and
the method further comprises:
forming a third through hole penetrating through the second insulating structure material layer, the first support material layer, and the first sacrificial-material layer, the third through hole being located between adjacent two of the first electrode structures, a sidewall of the third through hole exposing part of the first electrode layer and part of the second electrode layer, and a bottom of the third through hole exposing the first insulating material layer;
wherein the forming the capacitor dielectric layer comprising:
forming a first sub-capacitor dielectric layer covering the exposed part of the first electrode layer; and
forming a second sub-capacitor dielectric layer covering the exposed part of the second electrode layer, the capacitor dielectric layer comprising the first sub-capacitor dielectric layer and the second sub-capacitor dielectric layer; and
wherein the forming the second electrode structure comprises:
forming the first part covering the first sub-capacitor dielectric layer; and
forming the second part covering the second sub-capacitor dielectric layer.

14. The method of claim 13, wherein:
the forming the third through hole penetrating through the second insulating structure material layer, the first support material layer, and the first sacrificial-material layer comprises:
etching down the second support material layer according to a mask pattern to form a first opening, a bottom of the first opening exposing the second sacrificial-material layer, and a remaining portion of the second support material layer constituting a second support layer;
removing the second sacrificial-material layer according to the first opening to form a first gap, a sidewall of the first gap exposing part of the second electrode layer, a bottom of the first gap exposing the first support material layer, and the second insulating structure comprising the second support layer;
etching down the first support material layer according to the mask pattern to form a second opening, a bottom of the second opening exposing the first sacrificial-material layer, and a remaining portion of the first support material layer constituting a first support layer; and
removing the first sacrificial-material layer according to the second opening to form a second gap, a sidewall of the second gap exposing part of the first electrode layer, a bottom of the second gap exposing the first insulating material layer, a remaining portion of the first insulating material layer constituting a first insulating layer, and the first insulating structure comprising the first insulating layer and the first support layer.

15. The method of claim 14, wherein:
the forming the first sub-capacitor dielectric layer covering the exposed part of the first electrode layer comprises:
forming the first sub-capacitor dielectric layer in the second gap,
the forming the first part covering the first sub-capacitor dielectric layer comprises:
forming the first part in the second gap formed with the first sub-capacitor dielectric layer,
the forming the second sub-capacitor dielectric layer covering the exposed part of the second electrode layer comprises:
forming the second sub-capacitor dielectric layer in the first gap, and
the forming the second part covering the second sub-capacitor dielectric layer comprises:
forming the second part in the first gap formed with the second sub-capacitor dielectric layer.

16. The method of claim 15, wherein:
the second insulating structure material layer further comprises a third sacrificial-material layer and a third support material layer stacked in turn, the third sacrificial-material layer being located between the second support material layer and the third support material layer,
the forming the third through hole penetrating through the second insulating structure material layer, the first support material layer, and the first sacrificial-material layer comprises:
etching down the third support material layer according to the mask pattern to form a third opening, a bottom of the third opening exposing the third sacrificial-material layer, and a remaining portion of the third support material layer constituting a third support layer; and
removing the third sacrificial-material layer according to the third opening to form a third gap, a sidewall of the third gap exposing part of the second electrode layer, a bottom of the third gap exposing the second support material layer, and the second insulating structure further comprising the third support layer.

17. The method of claim 16, wherein:
the forming the second sub-capacitor dielectric layer covering the exposed part of the second electrode layer further comprises:
forming the second sub-capacitor dielectric layer in the third gap, and the forming the second part covering the second sub-capacitor dielectric layer comprises:
forming the second part in the third gap formed with the second sub-capacitor dielectric layer.

18. The method of claim 16, wherein an etch-selectivity ratio of the second sacrificial-material layer is greater than that of the third sacrificial-material layer.

19. A memory system, comprising:
a memory, comprising:
a first semiconductor structure comprising a vertical transistor;
a first insulating structure and a second insulating structure stacked in turn on the first semiconductor structure;
a contact structure penetrating through the first insulating structure and connected with a semiconductor body of the vertical transistor;
a first electrode structure comprising a first electrode layer penetrating through at least part of the first insulating structure and a second electrode layer penetrating through the second insulating structure, the first electrode layer covering a sidewall of at least part of the contact structure and being connected with the contact structure, and the second electrode layer being connected with the first electrode layer;
a second electrode structure comprising a first part in the first insulating structure and a second part in the second insulating structure, the first part covering a sidewall of part of the first electrode layer, and the second part covering a sidewall of part of the second electrode layer; and
a capacitor dielectric layer between the first electrode structure and the second electrode structure; and
a memory controller coupled to the memory and configured to control the memory.

20. An electronic device, comprising:
a memory system, comprising:
a memory, comprising:
a first semiconductor structure comprising a vertical transistor;
a first insulating structure and a second insulating structure stacked in turn on the first semiconductor structure;
a contact structure penetrating through the first insulating structure and connected with a semiconductor body of the vertical transistor;
a first electrode structure comprising a first electrode layer penetrating through at least part of the first insulating structure and a second electrode layer penetrating through the second insulating structure, the first electrode layer covering a sidewall of at least part of the contact structure and being connected with the contact structure, and the second electrode layer being connected with the first electrode layer;
a second electrode structure comprising a first part in the first insulating structure and a second part in the second insulating structure, the first part covering a sidewall of part of the first electrode layer, and the second part covering a sidewall of part of the second electrode layer; and
a capacitor dielectric layer between the first electrode structure and the second electrode structure; and
a memory controller coupled to the memory and configured to control the memory; and
a host coupled to the memory system.
